(19) United States
(12) Patent Application Publication
(10) Pub. No.: US 2026/0310060 A1
(43) Pub. Date: Oct. 8, 2026

(54) EUV PHOTOMASK AND MANUFACTURING METHOD THEREOF

(71) Applicant: Taiwan Semiconductor Manufacturing Company, Ltd., Hsinchu (TW)

(72) Inventors: Howard Yi Fan SIM, Hsinchu (TW); Chun-Lien WU, Taipei (TW); Kuan-Wen LIN, Taichung (TW); Yu-Sheng YIN, Hsinchu (TW); Li-Tzu TING, Hsinchu (TW); William Hao-Cheng HUANG, Taoyuan (TW); Chia-Jen CHEN, Hsinchu (TW); Hsin-Chang LEE, Zhubei (TW)

(73) Assignee: Taiwan Semiconductor Manufacturing Company, Ltd., Hsinchu (TW)

(21) Appl. No.: 19/349,617

(22) Filed: Oct. 3, 2025

Related U.S. Application Data
(60) Provisional application No. 63/782,899, filed on Apr. 3, 2025.

(51) Int. Cl. G03F 1/24; G03F 1/52; G03F 1/54; G03F 1/80; G03F 1/82

(52) U.S. Cl. CPC G03F 1/24; G03F 1/52; G03F 1/54; G03F 1/80; G03F 1/82

(57) ABSTRACT

A method of manufacturing an extreme ultraviolet mask includes forming a reflective multilayer stack, a capping layer, an absorber layer, and a hard mask layer over a substrate in sequence. A photoresist layer is formed over the hard mask layer, and the photoresist layer is patterned. The hard mask layer is etched to form a hard mask. The absorber layer is etched to form a patterned absorber layer. The patterned photoresist layer and the hard mask are removed. A first plasma treatment is performed using a plasma formed from a mixture of oxygen and water. The plasma is purged using a mixture of H₂ and an inert gas. A second plasma treatment is performed using a plasma formed from a mixture of H₂ and an inert gas; and a wet cleaning operation is performed.

### RELATED APPLICATION

This application claims priority to U.S. Provisional Patent Application No. 63/782,899 filed on Apr. 3, 2025, the entire content of which is incorporated herein by reference.

### BACKGROUND

Photolithography operations are one of the key operations in the semiconductor manufacturing process. Photolithography techniques include ultraviolet lithography, deep ultraviolet lithography, and extreme ultraviolet (EUV) lithography. The photomask is an important component in photolithography operations. It is important to fabricate EUV photomasks having a high contrast between a high reflectivity part and a high absorption part.

During the EUV photomask fabrication process, critical dimension loss can occur during the mask patterning operations. During the mask patterning and cleaning operations, oxygen and/or water vapor plasma treatments, which aid in modifying mask surface wettability, may result in 1) large critical dimension loss after mask wet cleaning, and 2) ruthenium capping layer oxidation, which weakens the capping layer's ability to protect the multilayer from damage.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 is a schematic view of an EUV lithography system with a laser produced plasma (LPP) EUV radiation source in accordance with some embodiments of the present disclosure.

FIG. 2 shows a schematic diagram of an extreme ultraviolet lithography tool according to an embodiment of the disclosure.

FIGS. 3A, 3B, 3C, 3D, and 3E show EUV photomask blanks according to embodiments of the present disclosure.

FIGS. 4, 5, 6, 7, 8, 9A, 9B, 10, and 11 schematically illustrate methods of fabricating an EUV photomask according to an embodiment of the present disclosure.

FIGS. 12, 13, 14, 15, 16, 17A, 17B, 18, 19, 20, 21, 22, and 23 schematically illustrate a method of fabricating an EUV photomask according to an embodiment of the present disclosure.

FIG. 24 shows a flow chart of manufacturing an EUV photomask according to embodiments of the present disclosure.

FIG. 25 shows a flow chart of manufacturing an EUV photomask according to embodiments of the present disclosure.

FIG. 26 shows a flow chart of manufacturing an EUV photomask according to embodiments of the present disclosure.

FIG. 27 shows a flow chart of manufacturing an EUV photomask according to embodiments of the present disclosure.

FIGS. 28A, 28B, 28C, and 28D show a sequential manufacturing operation of a method of making a semiconductor device in accordance with embodiments of present disclosure.

### DETAILED DESCRIPTION

It is to be understood that the following disclosure provides many different embodiments, or examples, for implementing different features of the invention. Specific embodiments or examples of components and arrangements are described below to simplify the present disclosure. These are, of course, merely examples and are not intended to be limiting. For example, dimensions of elements are not limited to the disclosed range or values, but may depend upon process conditions and/or desired properties of the device. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. Various features may be arbitrarily drawn in different scales for simplicity and clarity.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. In addition, the term “made of” may mean either “comprising” or “consisting of.” In the present disclosure, a phrase “one of A, B and C” means “A, B and/or C” (A, B, C, A and B, A and C, B and C, or A, B and C), and does not mean one element from A, one element from B and one element from C, unless otherwise described.

Embodiments of the present disclosure provide a method of manufacturing an EUV photomask. More specifically, the present disclosure provides techniques to improve the profile of the circuit pattern formed in the absorber layer of the EUV photomask. Embodiments of the present disclosure inhibit photomask critical dimension loss during patterning and cleaning operations.

EUV lithography employs scanners using light in the extreme ultraviolet (EUV) region. The mask is a critical component of an EUV lithography system. Because the optical materials are not transparent to EUV radiation, EUV photomasks are reflective masks. Circuit patterns are formed in an absorber layer disposed over a reflective structure. The absorber has a low EUV reflectivity, for example, less than 3-5%.

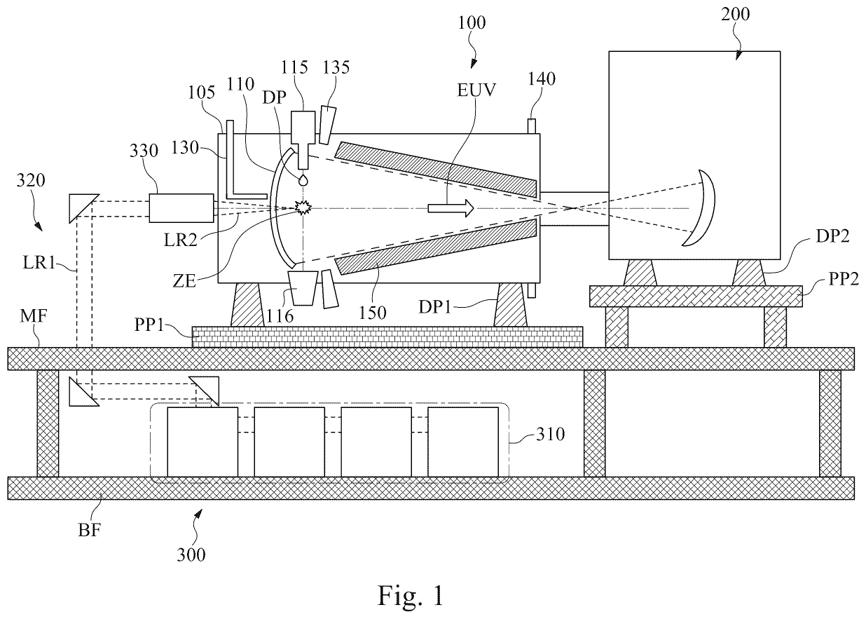

FIG. 1 is a schematic and diagrammatic view of an EUV lithography system. The EUV lithography system includes an EUV radiation source apparatus 100 to generate EUV light, an exposure tool 200, such as a scanner, and an excitation laser source apparatus 300. As shown in FIG. 1, in some embodiments, the EUV radiation source apparatus 100 and the exposure tool 200 are installed on a main floor MF of a clean room, while the excitation laser source apparatus 300 is installed in a base floor BF located under the main floor. Each of the EUV radiation source apparatus 100 and the exposure tool 200 are placed over pedestal plates PP1 and PP2 via dampers DP1 and DP2, respectively. The EUV radiation source apparatus 100 and the exposure tool 200 are coupled to each other by a coupling mechanism, which may include a focusing unit.

The EUV lithography system is designed to expose a resist layer by EUV light (or EUV radiation). The resist layer is a material sensitive to the EUV light. The EUV lithography system employs the EUV radiation source apparatus 100 to generate EUV light, such as EUV light having a wavelength ranging between about 1 nm and about 100 nm. In one particular example, the EUV radiation source 100 generates an EUV light with a wavelength centered at about 13.5 nm. In the present embodiment, the EUV radiation source 100 utilizes a mechanism of laser-produced plasma (LPP) to generate the EUV radiation.

The exposure tool 200 includes various reflective optic components, such as convex/concave/flat mirrors, a mask holding mechanism including a mask stage, and wafer holding mechanism. The EUV radiation generated by the EUV radiation source 100 is guided by the reflective optical components onto a mask secured on the mask stage. In some embodiments, the mask stage includes an electrostatic chuck (e-chuck) to secure the mask. Because gas molecules absorb EUV light, the lithography system for the EUV lithography patterning is maintained in a vacuum or a low pressure environment to avoid EUV intensity loss.

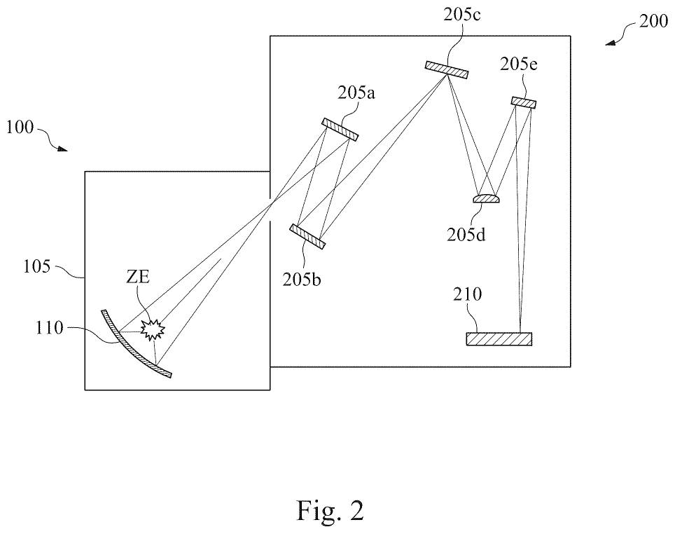

FIG. 2 is a schematic diagram of a detail of an extreme ultraviolet lithography tool according to an embodiment of the disclosure showing the exposure of photoresist coated substrate 210 with a patterned beam of EUV light. The exposure device 200 is an integrated circuit lithography tool such as a stepper, scanner, step and scan system, direct write system, device using a contact and/or proximity mask, etc., provided with one or more optics 205a, 205b, for example, to illuminate a patterning optic 205c, such as a reticle, with a beam of EUV light, to produce a patterned beam, and one or more reduction projection optics 205d, 205e, for projecting the patterned beam onto the substrate 210. A mechanical assembly (not shown) may be provided for generating a controlled relative movement between the substrate 210 and patterning optic 205c. As further shown in FIG. 2, the EUV lithography tool includes an EUV light source 100 including plasma at ZE emitting EUV light in a chamber 105 that is collected and reflected by a collector 110 along a path into the exposure device 200 to irradiate the substrate 210.

As used herein, the term “optic” is meant to be broadly construed to include, and not necessarily be limited to, one or more components which reflect and/or transmit and/or operate on incident light, and includes, but is not limited to, one or more lenses, windows, filters, wedges, prisms, grisms, gratings, transmission fibers, etalons, diffusers, homogenizers, detectors and other instrument components, apertures, axicons, and mirrors including multi-layer mirrors, near-normal incidence mirrors, grazing incidence mirrors, specular reflectors, diffuse reflectors, and combinations thereof. Moreover, unless otherwise specified, the term “optic,” as used herein, is not meant to be limited to components which operate solely within one or more specific wavelength ranges such as at the EUV output light wavelength, the irradiation laser wavelength, a wavelength suitable for metrology, or any other specific wavelength.

In the present disclosure, the terms mask, photomask, and reticle are used interchangeably. In the present embodiment, the mask is a reflective mask. One exemplary structure of the mask includes a substrate with a suitable material, such as a low thermal expansion material or fused quartz. In various examples, the material includes TiO₂ doped SiO₂, or other suitable materials with low thermal expansion. The mask includes multiple reflective layers deposited on the substrate. The multiple layers include a plurality of film pairs, such as molybdenum-silicon (Mo/Si) film pairs (e.g., a layer of molybdenum above or below a layer of silicon in each film pair). Alternatively, the multiple layers may include molybdenum-beryllium (Mo/Be) film pairs, or other suitable materials that are configurable to highly reflect the EUV light. The mask may further include a capping layer, such as ruthenium (Ru), disposed on the multiple reflective layers for protection. The mask further includes an absorber layer, such as a chromium nitride (CrN) or tantalum boron nitride (TaBN) layer, deposited over the multiple layers. The absorber layer is patterned to define a layer of an integrated circuit (IC). Alternatively, another reflective layer may be deposited over the multiple layers and is patterned to define a layer of an integrated circuit, thereby forming an EUV phase shift mask.

In the present embodiments, the semiconductor substrate is a semiconductor wafer, such as a silicon wafer or other type of wafer to be patterned. The semiconductor substrate is coated with a resist layer sensitive to the EUV light in the present disclosure. Various components including those described above are integrated together and are operable to perform lithography exposing processes. The lithography system may further include other modules or be integrated with (or be coupled with) other modules.

As shown in FIG. 1, the EUV radiation source 100 includes a target droplet generator 115 and a LPP collector 110, enclosed by a chamber 105. The target droplet generator 115 generates a plurality of target droplets DP. In some embodiments, the target droplets DP are tin (Sn) droplets. In some embodiments, the tin droplets each have a diameter about 30 microns (μm). In some embodiments, the tin droplets DP are generated at a rate about 50-50,000 droplets per second and are introduced into a zone of excitation ZE at a speed about 70 meters per second (m/s). Other materials can also be used for the target droplets, for example, a tin containing liquid material such as eutectic alloy containing tin or lithium (Li).

The excitation laser LR2 generated by the excitation laser source apparatus 300 is a pulse laser. In some embodiments, the excitation laser includes a pre-heat laser and a main laser. The pre-heat laser pulse is used to heat (or pre-heat) the target droplet to create a low-density target in a pancake shape, which is subsequently heated (or reheated) by the main laser pulse, generating increased emission of EUV light. In various embodiments, the pre-heat laser pulses have a spot size about 100 μm or less, and the main laser pulses have a spot size about 200-300 μm.

The laser pulses LR2 are generated by the excitation laser source 300. The laser source 300 may include a laser generator 310, laser guide optics 320 and a focusing apparatus 330. In some embodiments, the laser source 310 includes a carbon dioxide (CO₂) or a neodymium-doped yttrium aluminum garnet (Nd:YAG) laser source. The laser light LR1 generated by the laser generator 300 is guided by the laser guide optics 320 and focused into the excitation laser LR2 by the focusing apparatus 330, and then introduced into the EUV radiation source 100.

The laser light LR2 is directed through windows (or lenses) into the zone of excitation ZE. The windows adopt a suitable material substantially transparent to the laser beams. The generation of the pulse lasers is synchronized with the generation of the target droplets. As the target droplets move through the excitation zone, the pre-pulses heat the target droplets and transform them into low-density target in a pancake shape. A delay between the pre-pulse and the main pulse is controlled to allow the target in the pancake shape to form and to expand to an optimal size and geometry. When the main pulse heats the target in a pancake shape, a high-temperature plasma is generated. The plasma emits EUV radiation EUV, which is collected by the collector mirror 110. The collector 110 has a reflective surface that reflects and focuses the EUV radiation for the lithography exposing processes. In some embodiments, a droplet catcher 116 is installed opposite the target droplet generator 115. The droplet catcher 116 is used for catching excess target droplets. For example, some target droplets may be purposely missed by the laser pulses.

The collector 110 includes a proper coating material and shape to function as a mirror for EUV collection, reflection, and focusing. In some embodiments, the collector 110 is designed to have an ellipsoidal geometry. In some embodiments, the coating material of the collector 100 is similar to the reflective multilayer of the EUV mask. In some examples, the coating material of the collector 110 includes multiple layers (such as a plurality of Mo/Si film pairs) and may further include a capping layer (such as Ru) coated on the multiple layers to substantially reflect the EUV light. In some embodiments, the collector 110 further includes a grating structure designed to effectively scatter the laser beam directed onto the collector 110. For example, a silicon nitride layer is coated on the collector 110 and is patterned to have a grating pattern in some embodiments.

In such an EUV radiation source apparatus, the plasma caused by the laser application creates physical debris, such as ions, gases and atoms of the droplet, as well as the desired EUV radiation. It is necessary to prevent the accumulation of material on the collector 110 and also to prevent physical debris exiting the chamber 105 and entering the exposure tool 200.

As shown in FIG. 1, in some embodiments, a buffer gas is supplied from a first buffer gas supply 130 through the aperture in collector 110 by which the pulse laser is delivered to the tin droplets. In some embodiments, the buffer gas is H₂, He, Ar, N₂, or another inert gas. In certain embodiments, H₂ is used as H radicals generated by ionization of the buffer gas can be used for cleaning purposes. The buffer gas can also be provided through one or more second buffer gas supplies 135 toward the collector 110 and/or around the edges of the collector 110. Further, the chamber 105 includes one or more gas outlets 140 so that the buffer gas is exhausted outside the chamber 105. Hydrogen gas has low absorption of the EUV radiation. Hydrogen gas reaching the coating surface of the collector 110 reacts chemically with a metal of the droplet forming a hydride, e.g., metal hydride. When tin (Sn) is used as the droplet, stannane (SnH₄), which is a gaseous byproduct of the EUV generation process, is formed. The gaseous SnH₄ is then pumped out through the outlet 140. However, it is difficult to exhaust all gaseous SnH₄ from the chamber and to prevent the SnH₄ from entering the exposure tool 200. To trap the SnH₄ or other debris, one or more debris collection mechanisms or devices 150 are employed in the chamber 105.

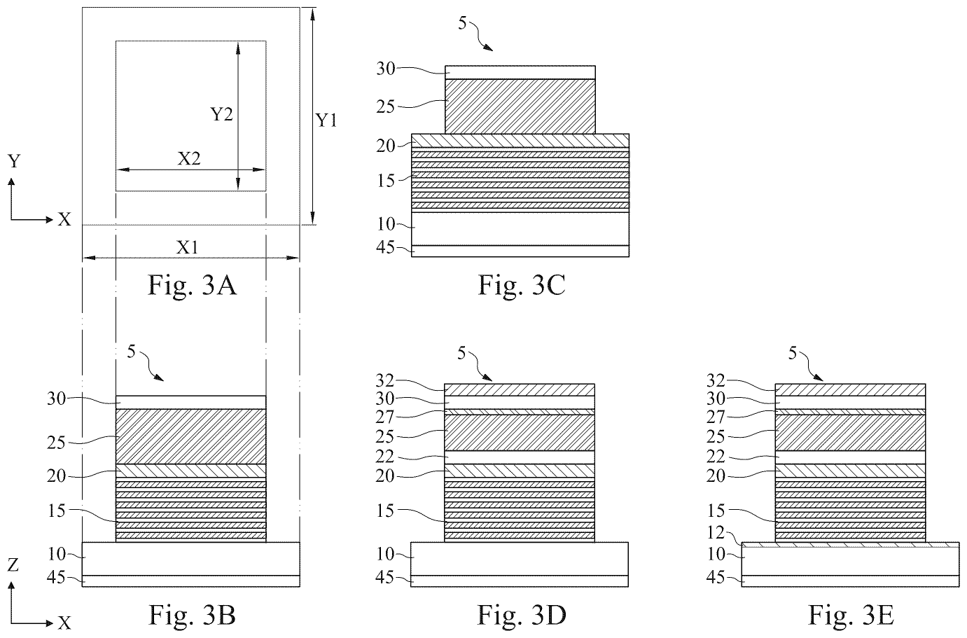

FIGS. 3A and 3B show an EUV reflective photomask blank according to an embodiment of the present disclosure. FIG. 3A is a plan view (viewed from the top) and FIG. 3B is a cross sectional view along the X direction.

In some embodiments, the EUV photomask with circuit patterns is formed from an EUV photomask blank 5. The EUV photomask blank 5 includes a substrate 10, a multilayer Mo/Si stack 15 of multiple alternating layers of silicon and molybdenum, a capping layer 20, an absorber layer 25, and a first hard mask layer 30. Further, a backside conductive layer 45 is formed on the backside of the substrate 10, as shown in FIG. 3B.

The substrate 10 is formed of a low thermal expansion material in some embodiments. In some embodiments, the substrate is a low thermal expansion glass or quartz, such as fused silica or fused quartz. In some embodiments, the low thermal expansion glass substrate transmits light at visible wavelengths, a portion of the infrared wavelengths near the visible spectrum (near-infrared), and a portion of the ultraviolet wavelengths. In some embodiments, the low thermal expansion glass substrate absorbs extreme ultraviolet wavelengths and deep ultraviolet wavelengths near the extreme ultraviolet. In some embodiments, the size of the substrate 10 is 152 mm×152 mm having a thickness of about 20 mm. In other embodiments, the size of the substrate 10 is smaller than 152 mm×152 mm and equal to or greater than 148 mm×148 mm. The shape of the substrate 10 is square or rectangular.

In some embodiments, the functional layers above the substrate (e.g., the multilayer Mo/Si stack 15, the capping layer 20, the absorber layer 25, the first hard mask layer 30) have a smaller width than the substrate 10. In some embodiments, the size of the functional layers ranges from about 138 mm×138 mm to about 142 mm×142 mm. The shape of the functional layers is square or rectangular as seen in plan view in some embodiments.

In other embodiments, the absorber layer 25 and the first hard mask layer 30 have a smaller size, ranging from about 138 mm×138 mm to about 142 mm×142 mm, than the substrate 10, the multilayer Mo/Si stack 15 and the capping layer 20 as shown in FIG. 3C. The smaller size of one or more of the functional layers can be formed by using a frame shaped cover having an opening ranging from about 138 mm×138 mm to about 142 mm×142 mm, when forming the respective layers by, for example, sputtering. In other embodiments, all of the layers above the substrate 10 have the same size as the substrate 10.

In some embodiments, the Mo/Si multilayer stack 15 includes from about 30 alternating layers each of silicon and molybdenum to about 60 alternating layers each of silicon and molybdenum. In certain embodiments, from about 40 to about 50 alternating layers each of silicon and molybdenum are formed. In some embodiments, the multilayer stack includes 40±1 pairs of molybdenum and silicon layers. In some embodiments, the reflectivity is higher than about 70% for wavelengths of interest (e.g., 13.5 nm). In some embodiments, the silicon and molybdenum layers are formed by chemical vapor deposition (CVD), plasma-enhanced CVD (PECVD), atomic layer deposition (ALD), physical vapor deposition (PVD) including sputtering, or any other suitable film forming method. Each layer of silicon and molybdenum is about 2 nm to about 10 nm thick. In some embodiments, the layers of silicon and molybdenum are about the same thickness. In other embodiments, the layers of silicon and molybdenum are different thicknesses. In some embodiments, the thickness of each silicon layer is about 4 nm and the thickness of each molybdenum layer is about 3 nm.

In other embodiments, the multilayer stack 15 includes alternating molybdenum layers and beryllium layers. In some embodiments, the number of layers in the multilayer stack 15 is in a range from about 20 to about 100 although any number of layers is allowed as long as sufficient reflectivity is maintained for imaging the target substrate. In some embodiments, the reflectivity is higher than about 70% for wavelengths of interest e.g., 13.5 nm. In some embodiments, the multilayer stack 15 includes about 30 to about 60 alternating layers of Mo and Be. In other embodiments of the present disclosure, the multilayer stack 15 includes about 40 to about 50 alternating layers each of Mo and Be.

The capping layer 20 is disposed over the Mo/Si multilayer 15 to prevent oxidation of the multilayer stack 15 in some embodiments. In some embodiments, the capping layer 20 is made of ruthenium, a ruthenium alloy (e.g., RuNb, RuZr, RuZrN, RuRh, RuNbN, RuRhN, RuV, or RuVN) or a ruthenium based oxide (e.g., RuO₂, RuNbO, RuVO, or RuON), having a thickness of from about 2 nm to about 10 nm. In certain embodiments, the thickness of the capping layer 20 ranges from about 2 nm to about 5 nm. In some embodiments, the capping layer 20 has a thickness of 3.5 nm±10%. In some embodiments, the capping layer 20 is formed by CVD, PECVD, ALD, PVD (e.g., sputtering), or any other suitable film forming method. In other embodiments, a Si layer is used as the capping layer 20.

In some embodiments, a protection (intermediate) layer 22 is formed between the capping layer 20 and the absorber layer 25, as shown in FIG. 3D. Also in some embodiments, an oxide layer 27 is formed on the top surface of the absorber layer 25, as shown in FIG. 3D. In some embodiments, the hard mask layer further includes a second hard mask layer 32 formed over the first hard mask layer 30, as shown in FIG. 3D. In some embodiments the first hard mask layer 30 and the second hard mask layer 32 are made of different materials. In some embodiments, the mask blank 5 includes the protection layer 22, the oxide layer 27, and the second hard mask layer 32. In other embodiments, the mask blank includes only two of any combination of the protection layer 22, the oxide layer 27, and the second hard mask layer 32. In some embodiments, the mask blank includes only one of the protection layer 22, the oxide layer 27, and the second hard mask layer 32.

The protection layer 22 protects the capping layer 20 in some embodiments. In some embodiments, the protection layer 22 includes a Ta-based material, such as TaB, TaO, TaBO or TaBN; silicon; a silicon-based compound (e.g., silicon oxide, silicon nitride, SiON, or MoSi); ruthenium; or a ruthenium-based compound (Ru or RuB). The protection layer 22 has a thickness of about 2 nm to about 20 nm in some embodiments. In some embodiments, the protection layer 22 is formed by CVD, PECVD, ALD, PVD, or any other suitable film forming method. In some embodiments, the protection layer 22 functions as an etching stop layer during a patterning operation of the absorber layer.

In other embodiments, the intermediate layer 22 is a photocatalytic layer that can catalyze hydrocarbon residues formed on the photomask into CO₂ and/or H₂O with EUV radiation. Thus, an in-situ self-cleaning of the mask surface is performed. In some embodiments, in the EUV scanner system, oxygen and hydrogen gases are injected into the EUV chamber to maintain the chamber pressure (e.g., at about 2 Pa). The chamber background gas can be a source of oxygen. In addition to the photocatalytic function, the photocatalytic layer is designed to have sufficient durability and resistance to various chemicals and various chemical processes, such as cleaning and etching. Ozonated water may be used to make the EUV reflective mask in a mask making process. The ozonated water may damage the capping layer 20 made of Ru, which can result in a significant EUV reflectivity drop. Further after Ru oxidation, Ru oxide is easily etched away by an etchant, such as C1₂ or CF₄ gas. In some embodiments, the photocatalytic layer includes one or more of titanium oxide (TiO₂), tin oxide (SnO), zinc oxide (ZnO), and cadmium sulfide (CdS). The thickness of the photocatalytic layer 22 ranges from about 2 nm to about 10 nm in some embodiments, and ranges from about 3 nm to about 7 nm in other embodiments. When the thickness is too thin, the photocatalytic layer may not sufficiently function as an etch stop layer. When the thickness is too large, the photocatalytic layer may absorb the EUV radiation.

In some embodiments, the intermediate layer 22 is antireflective layer. The antireflective layer 22 is made of a silicon oxide in some embodiments, and has a thickness of from about 2 nm to about 10 nm. In other embodiments, a TaBO layer having a thickness ranging from about 12 nm to about 18 nm is used as the antireflective layer 22. In some embodiments, the thickness of the antireflective layer 22 ranges from about 3 nm to about 6 nm. In some embodiments, the antireflective layer 22 is formed by CVD, PECVD, ALD, PVD, or any other suitable film forming method.

The absorber layer 25 is disposed over the intermediate (protection) layer 22 in some embodiments, in other embodiments the absorber layer is disposed over the capping layer 20 without an intervening protection layer. In some embodiments, the absorber layer 25 includes a Cr-based material, such as Cr, CrN, CrON, and/or CrCON. In the case of CrON or CrCON, a nitrogen amount is in a range from about 10 atomic % to about 30 atomic % in some embodiments. In some embodiments, the absorber layer 25 has a multilayered structure of Cr, CrN, CrON, and/or CrCON.

In certain embodiments, a CrN layer is used as the absorber layer 25. When the CrN layer is used, the nitrogen amount ranges from about 16 atomic % to about 40 atomic % in some embodiments. When the nitrogen amount ranges from about 16 atomic % to about 30 atomic % in some embodiments, the CrN absorber layer includes Cr and Cr₂N phases. When the nitrogen amount ranges from about 30 atomic % to about 33 atomic % in some embodiments, the CrN absorber layer is substantially made of a Cr₂N phase (e.g., more than 95 vol %). When the nitrogen amount ranges from about 33 atomic % to about 40 atomic % in some embodiments, the CrN absorber layer includes Cr₂N and CrN phases. The phases can be observed by electron energy loss spectroscopy (EELS), transmission electron microscopy (TEM), and/or an X-ray diffraction (XRD) analysis. In some embodiments, the two phases form a solid solution.

In some embodiments, a nitrogen concentration in the absorber layer 25 is not uniform. In some embodiments, the nitrogen concentration is higher in the middle or the center of the absorber layer 25 than a surface region of the absorber layer 25. In some embodiments, the CrN absorber layer includes one or more impurities other than Cr and N in an amount of less than about 5 atomic %. In some embodiments, the absorber layer 25 further includes one or more elements of Co, Te, Hf, and/or Ni.

In some embodiments, the thickness of the absorber layer 25 ranges from about 20 nm to about 50 nm, and ranges from about 35 nm to about 46 nm in other embodiments.

The oxide layer 27 includes one or more of Cr₂O₃ or CrO₂ in some embodiments. In some embodiments, the oxide layer 27 is formed during the manufacturing operation of the mask blank. In some embodiments, the thickness of the oxide layer 27 ranges from about 1 nm to about 3 nm.

The first hard mask layer 30 is disposed over the oxide layer 27 in some embodiments. The first hard mask layer 30 is formed over the absorber layer 25 in some embodiments. In some embodiments, the first hard mask layer 30 is made of a Ta-based material, such as TaB, TaO, TaBO or TaBN. In other embodiments, the first hard mask layer 30 is made of silicon, a silicon-based compound (e.g., silicon oxide, silicon nitride, SiON, or MoSi), ruthenium or a ruthenium-based compound (Ru or RuB). In some embodiments, the first hard mask layer 30 is made of the same or similar material as the protection layer 22. The first hard mask layer 30 has a thickness of about 2 nm to about 20 nm in some embodiments. In some embodiments, the first hard mask layer 30 is formed by CVD, PECVD, ALD, PVD, or any other suitable film forming method.

The second hard mask layer 32 is disposed over the first hard mask layer 30 in some embodiments. In some embodiments, the second hard mask layer 32 is made of one or more of GaN, CrON, CrCON, silicon oxide, SiCO, and/or yttrium oxide. The second hard mask layer 32 has a thickness of about 2 nm to about 20 nm in some embodiments. The second hard mask layer 32 is smaller or larger than the thickness of the first hard mask layer 30, in some embodiments. In some embodiments, the second hard mask layer 32 is formed by CVD, PECVD, ALD, PVD, or any other suitable film-forming method.

In some embodiments, the second hard mask layer 32 is made of a material having a higher etching rate for a plasma including chlorine and oxygen than a material of the first hard mask layer 30. In some embodiments, the first hard mask layer 30 is made of a material having a higher etching rate for a plasma including fluorine than a material of the second hard mask layer 32.

In some embodiments, one or more of the functional layers above the substrate (e.g., the multilayer Mo/Si stack 15, the capping layer 20, the protection layer 22, the absorber layer 25, the oxide layer 27, the first hard mask layer 30 and the second hard mask layer 32) have a poly-crystalline structure (e.g., nano-crystalline structure) or an amorphous structure.

In some embodiments, a backside conductive layer 45 is disposed on a second main surface of the substrate 10 opposing the first main surface of the substrate 10 on which the Mo/Si multilayer 15 is formed. In some embodiments, the backside conductive layer 45 is made of TaB (tantalum boride) or other Ta-based conductive material. In some embodiments, the tantalum boride is crystalline. The crystalline tantalum boride includes at least one of TaB, Ta₅B₆, Ta₃B₄, and TaB₂. In other embodiments, the tantalum boride is polycrystalline or amorphous. In other embodiments, the backside conductive layer 45 is made of a Cr-based conductive material (CrN or CrON). In some embodiments, the sheet resistance of the backside conductive layer 45 is equal to or smaller than 20 Ω/□. In certain embodiments, the sheet resistance of the backside conductive layer 45 is equal to or more than 0.1 Ω/□. In some embodiments, the surface roughness Ra of the backside conductive layer 45 is equal to or smaller than 0.25 nm. In certain embodiments, the surface roughness Ra of the backside conductive layer 45 is equal to or more than 0.05 nm. Further, in some embodiments, the flatness of the backside conductive layer 45 is equal to or less than 50 nm (within the EUV photo mask). In some embodiments, the flatness of the backside conductive layer 45 is more than 1 nm. A thickness of the backside conductive layer 45 ranges from about 50 nm to about 400 nm in some embodiments. In other embodiments, the backside conductive layer 45 has a thickness of about 50 nm to about 100 nm. In certain embodiments, the thickness ranges from about 65 nm to about 75 nm. In some embodiments, the backside conductive layer 45 is formed by atmospheric CVD, low pressure CVD, PECVD, laser-enhanced CVD, ALD, molecular beam epitaxy (MBE), PVD including thermal deposition, pulsed laser deposition, electron-beam evaporation, ion beam assisted evaporation, and sputtering, or any other suitable film forming method. In cases of CVD, source gases include TaCl₅ and BCl₃ in some embodiments.

In some embodiments, as shown in FIG. 3E, a substrate protection layer 12 is formed between the substrate 10 and the multilayer stack 15. In some embodiments, the substrate protection layer 12 is made of Ru or a Ru compound, such as RuO, RuNb, RuNbO, RuZr, and RuZrO. In some embodiments, the substrate protection layer 12 is made of the same material as or different material from the capping layer 20. The thickness of the substrate protection layer 12 ranges from about 2 nm to about 10 nm in some embodiments. In some embodiments, the substrate protection layer 12, second hard mask layer 32, oxide layer 27, and protection layer 22 are included in the mask blank 5. In other embodiments, only one of substrate protection layer 12, second hard mask layer 32, oxide layer 27, and protection layer 22 are included in the mask blank 5. In other embodiments, any combination of the substrate protection layer 12, second hard mask layer 32, oxide layer 27, and protection layer 22 are included in the mask blank 5.

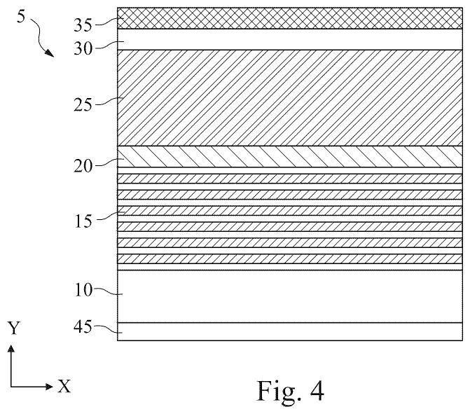

FIGS. 4-11 schematically illustrate a method of fabricating an EUV photomask for use in EUV lithography. It is understood that additional operations can be provided before, during, and after the processes shown by FIGS. 4-11, and some of the operations described below can be replaced or eliminated for additional embodiments of the method. The order of the operations/processes may be interchangeable.

In the fabrication of an EUV photomask, a first photoresist layer 35 is formed over the first hard mask layer 30 of the EUV photomask blank 5 in some embodiments, as shown in FIG. 4. Before the first photoresist layer 35 is formed, the EUV photomask blank is subject to inspection in some embodiments.

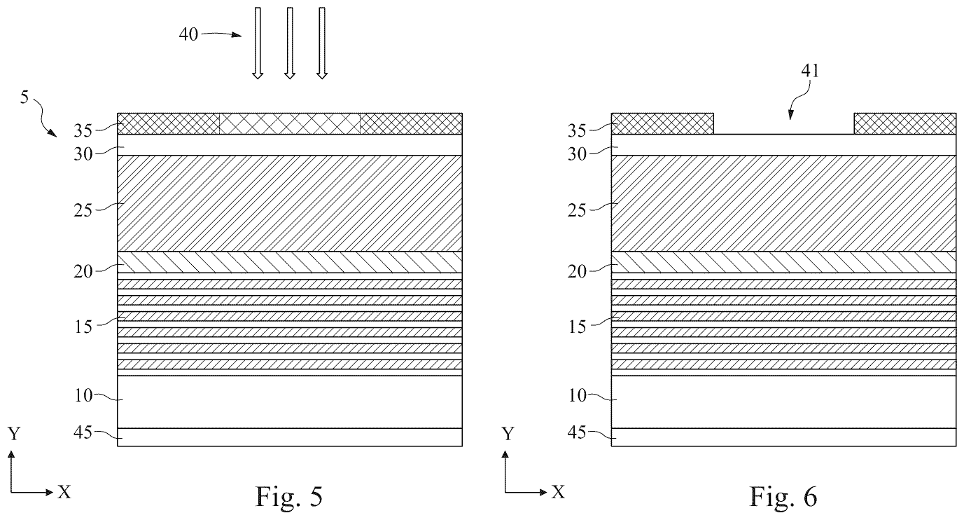

The photoresist layer 35 is patterned to form at least one opening 41 exposing the hard mask layer 30 in some embodiments. The photoresist layer 35 is patterned by selectively exposing the photoresist layer 35 to actinic radiation 40, as shown in FIG. 5, and then developing the selectively exposed photoresist layer 35 is to form the at least one opening 41, as shown in FIG. 6. In some embodiments, the actinic radiation 40 is an electron beam or an ion beam. In the embodiment shown in FIGS. 5 and 6, the photoresist layer is made of a positive-tone photoresist wherein the portion of the photoresist exposed to actinic radiation is removed during development. In other embodiments, the photoresist is a negative-tone photoresist where the portion of the photoresist layer not exposed to actinic radiation is removed during development. In some embodiments, the opening 41 corresponds to a pattern of semiconductor device features for which the EUV photomask will be used to form in subsequent operations. In some embodiments, the thickness of the first photoresist layer 35 disposed on the second hard mask layer 32 ranges from about 500 nm to about 1000 nm.

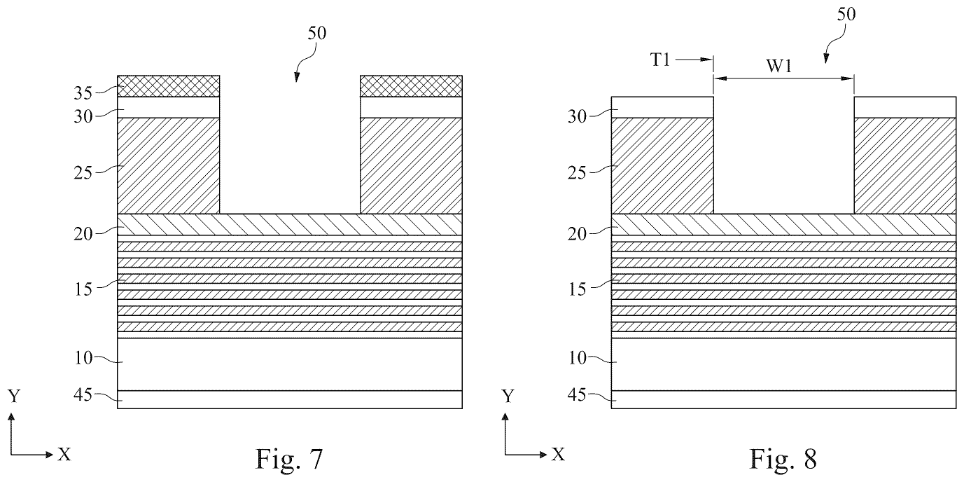

Next, the pattern 40 in the first photoresist layer 35 is extended into the first hard mask layer 30 and the absorber layer 25 forming a trench 50 in the absorber layer exposing the capping layer 20, as shown in FIG. 7. The opening 41 extended into the first hard mask layer 30 is formed by etching, in some embodiments, using a suitable wet or dry etchant that is selective to the first hard mask layer 30. In some embodiments, a plasma dry etching operation using a chlorine containing gas (e.g., Cl₂, HCl, BCl, and CCl₄) and an oxygen containing gas (e.g., O₂) is used to pattern the first hard mask layer 30 and absorber layer 25. In other embodiments, the plasma dry etching operation uses a fluorine containing gas (e.g., a fluorocarbon (CF₄, CHF₃, etc.) and SF₆) to pattern the first hard mask layer 30. In some embodiments, a different etchant is used to etch the first hard mask layer 30 and the absorber layer 25.

After the trench 50 is formed in the absorber layer is formed, the first photoresist layer 35 is removed by a photoresist stripper to expose the upper surface of the first hard mask layer 30, as shown in FIG. 8. In some embodiments, the photoresist layer 35 is removed after etching the opening in the first hard mask layer 30 and before extending the opening through the absorber layer 25.

In some embodiments, the trench 50 has a width W1 ranging from about 300 nm to about 1 μm. In some embodiments, after etching the trench there is no measurable oxide layer on the sidewalls of the trench. In other words, the trench 50 has a sidewall oxide layer having a thickness T1 of about 0 nm.

In some embodiments, the hard mask layer includes a first hard mask layer 30 and a second hard mask layer 32 disposed over the first hard mask layer 30, as shown in FIGS. 3D and 3E. In some embodiments, the material of the first hard mask layer 30 is selected to have a higher etching resistance (lower etching rate) against the plasma dry etching operation using chlorine and oxygen, and the etching substantially stops at the first hard mask layer 30 after extending the opening 41 into the second hard mask layer 32. Then, the pattern including at least one opening in the second hard mask layer 32 is extended into the first hard mask layer 30. In some embodiments, the pattern 41 extended into the first hard mask layer 30 using a different etchant, such a fluorine containing gas (e.g., a fluorocarbon (CF₄, CHF₃, etc.) and SF₆).

In embodiments including the oxide layer 27 disposed over the absorber layer 25, the oxide layer 27 is subsequently etched to expose the absorber layer 25. In some embodiments, the material of the oxide layer 27 is selected to have a higher etching resistance (lower etching rate) against the plasma dry etching operation using fluorine, and the etching of the first hard mask layer 30 substantially stops at the oxide layer 27.

Then, the pattern in the first and second hard mask layers 30, 32 is extended into the absorber layer 25 forming the trench 50 exposing portions of the capping layer 20 or the intermediate layer 22 in embodiments that include the intermediate layer.

The absorber layer 25 and oxide layer 27, if present, are etched by using a suitable wet or dry etchant that is selective to the first hard mask layer 30 and the intermediate layer 22, if present. In some embodiments, the material of the intermediate layer 22 is selected to have a higher etching resistance (lower etching rate) against the plasma dry etching operation of the absorber layer, and the etching substantially stops at the intermediate layer 22. In some embodiments, the second hard mask layer 32, if present, is removed during the etching of the oxide layer 27 and/or the absorber layer 25. In particular, when the second hard mask layer 32 is made of a Cr based material (e.g., CrN, CrON, or CrCON), the second hard mask layer 32 is removed during the etching of the oxide layer 27 and/or the absorber layer 25. If the second hard mask layer 32 remains after etching the absorber layer 25, an additional removal operation of the second hard mask layer 32 is performed in some embodiments by using a suitable wet or dry etching.

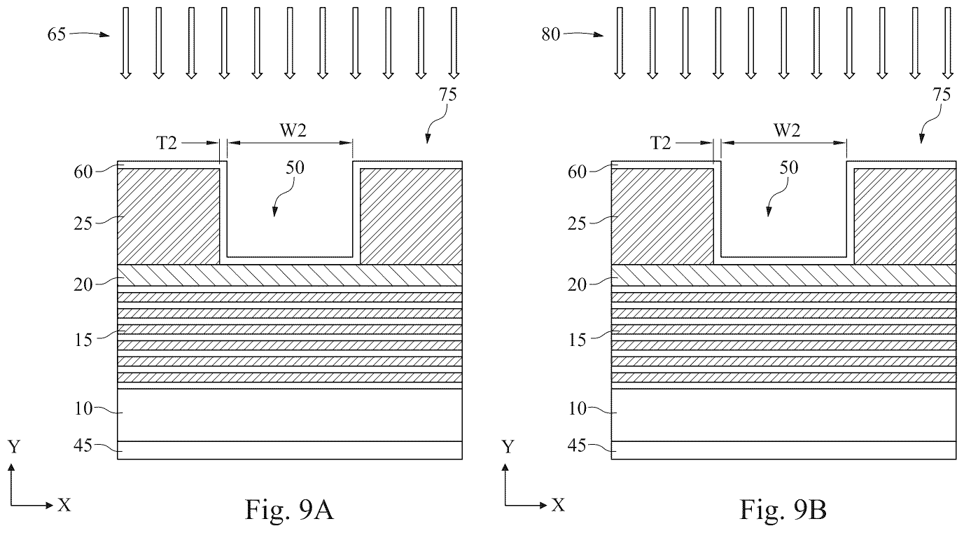

Then, the first hard mask layer 30 is removed using a suitable etching technique to form a photomask 75. In some embodiments, the etching is wet etching and/or dry etching. In some embodiments, the exposed portions of the intermediate layer 22, if present, is also removed. After removing the first hard mask layer in some embodiments, a first plasma treatment including a first plasma 65, is performed on the photomask 75, as shown in FIG. 9A. In some embodiments, the first plasma 65 is formed from a mixture of oxygen and water vapor. In some embodiments, the first plasma treatment is an inductively coupled plasma treatment. The oxygen plasma removes organic contaminants from the surface of the photomask 75. In oxygen/water vapor plasma cleaning, water vapor can be used as a process gas alongside oxygen to enhance the cleaning process. The water vapor can be used to break down organic contaminants, improve the removal of certain materials, and/or introduce a higher level of hydrophilicity to a surface.

A flow of oxygen and water vapor may initially be applied using a source power of about 0 W and a bias power of about 0 W prior to igniting the plasma. In some embodiments, an inert carrier gas is included in the gas flow. In some embodiments, the carrier gas is one or more selected from helium, neon, argon, xenon, and nitrogen. In some embodiments, the oxygen/water vapor plasma is applied at a source power of about 500 to about 1500 W, a bias power of about 0 W for a time from about 10 s to about 180 s. In some embodiments, the gas flow rate of the source gases for the plasma ranges from about 0.05 L/min to about 1 L/min, and from about 0.1 L/min to about 0.5 L/min in other embodiments. Parameters of the first plasma treatment below the disclosed ranges may result in insufficient organic contaminant removal, and at parameters of the first plasma treatment above the disclosed ranges there may be insignificant improvement in the organic contaminant removal.

However, the oxygen/water vapor plasma 65 also forms a thin oxide layer 60 on the surface of the absorber layer 25 and the exposed portions of the capping layer 20. The thin oxide layer 60 has a thickness T2 ranging from about 1 nm to about 5 nm in some embodiments. In other embodiments, the thin oxide layer 60 has a thickness T2 ranging from about 2.5 nm to about 3.5 nm. The formation of the thin oxide layer 60 decreases the width W2 of the trench by about 2 nm to about 10 nm, in some embodiments, and by about 5 nm to about 7 nm in other embodiments. In some embodiments, the width W2 of the trench after the first hard mask removal ranges from about 290 nm to about 998 nm in some embodiments, and about 295 nm to about 990 nm in other embodiments. The thin oxide layer 60 protects the absorber layer 25 and capping layer during subsequent wet cleaning operations. If the thickness T2 of thin oxide layer 60 is less than the disclosed range there may be insufficient protection of the absorber layer pattern and the capping layer. If the thickness T2 of the thin oxide layer 60 is greater than the disclosed range there may be loss of control of fine pattern detail and pattern resolution.

After the first plasma treatment, the processing chamber where the first hard mask layer is removed is purged for about 10 s to about 60 s with a gas mixture of hydrogen and an inert gas, such as helium, neon, argon, nitrogen, and combinations thereof. After the purging the processing chamber, the photomask 75 is subjected to a second plasma treatment using a plasma 80 formed from a mixture of hydrogen and an inert gas, as shown in FIG. 9B. In some embodiments, the plasma 80 is an inductively coupled plasma. In some embodiments, the concentration of hydrogen in the inert gas ranges from about 0.5 mol. % to about 10 mol. %, and from about 1 mol. % to about 5 mol. % in other embodiments. The inert gas may be selected from helium, neon, argon, nitrogen, and combinations thereof. In some embodiments, the inert gas is helium. In some embodiments, the first and second plasma treatments are performed in the same processing chamber. In other embodiments, the first and second plasma treatments are performed in different processing chambers. Concentrations of hydrogen below the disclosed ranges may result in insufficient protection of the oxide layer, and at concentrations of hydrogen above the disclosed ranges there may be insignificant improvement in the protection of the oxide layer.

In some embodiments, the inductively coupled plasma parameters during the plasma treatment of the photomask 75 include a source power ranging from about 500 W to about 4000 W with no bias power applied (bias power is about 0 W), and in other embodiments, the source power ranges from about 1000 W to about 3000 W with no bias power applied. In some embodiments, the gas flow rate of the source gases for the plasma ranges from about 0.1 L/min to about 3.5 L/min, and from about 0.25 L/min to about 2.5 L/min in other embodiments. The pressure in the processing chamber during the inductively coupled plasma treatment ranges from about 300 mTorr to about 3000 mTorr in some embodiments, and ranges from about 600 mTorr to about 1500 mTorr in other embodiments. The thin oxide layer 60 is exposed to the inductively coupled plasma treatment (or second plasma etch) for about 15 s to about 600 s in some embodiments and from about 30 s to about 300 s in other embodiments. In some embodiments, the inductively coupled plasma treatment is performed at a temperature ranging from about 20 °C to about 30 °C in some embodiments, and from about 24 °C to about 26 °C in other embodiments. Parameters of the second plasma treatment below the disclosed ranges may result in insufficient protection of the oxide layer, and parameters of the second plasma treatment above the disclosed ranges may result in insignificant improvement in the protection of the oxide layer.

In some embodiments, the second plasma etch converts water and/or acid soluble oxides on the surface of the absorber layer and capping layer into oxides that are insoluble in water and/or acid. For example, in some embodiments, the second plasma etch converts aqueous soluble chromium oxides with various chromium/oxygen ratios in the presence of hydrogen radicals to insoluble chromium oxides as follows:

CrₘO_{n(aq)}→Cr₂O₃ (s)+CrO₂(s). In some embodiments, the second plasma etch converts aqueous soluble ruthenium oxides with various ruthenium/oxygen ratios in the presence of hydrogen radicals to insoluble ruthenium oxides as follows:

RuO_{x(aq)}→RuO₂ (s)+RuO(s).

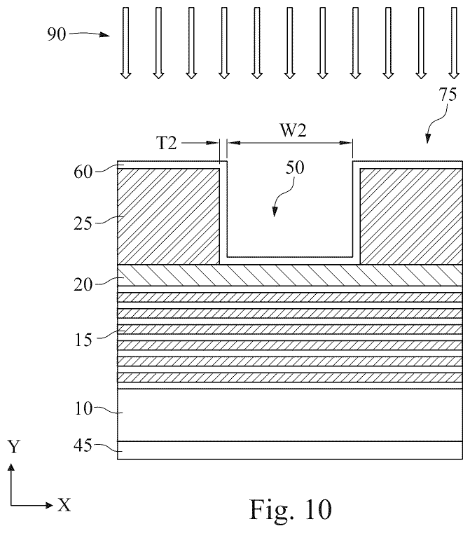

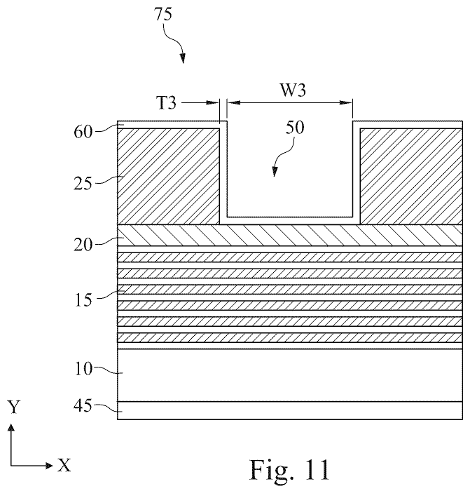

In some embodiments, the first stage of the cleaning process includes applying a reducing agent 90 to photomask 75 after the first hard mask layer 30 is removed, as shown in FIG. 10. In some embodiments, the reducing agent includes a hydrogen plasma, hydrogen gas, carbon monoxide, sodium borohydride, lithium aluminum hydride, hydrazine, hydrogen peroxide, sulfur dioxide, sodium dithionite, and/or ascorbic acid. The hydrogen plasma may include hydrogen radicals formed by ICP, as disclosed herein. In some embodiments the hydrogen plasma is formed from a mixture of hydrogen and an inert gas. In some embodiments, hydrogen gas is applied as a mixture of hydrogen and an inert gas. In some embodiments, the concentration of hydrogen in the inert gas ranges from about 0.5 mol. % to about 10 mol. %, and from about 1 mol. % to about 5 mol. % in other embodiments. The inert gas may be selected from helium, neon, argon, nitrogen, and combinations thereof. In some embodiments, the inert gas is helium. In some embodiments, the reducing agent is applied as a gas or a liquid. In some embodiments, the reducing agent is dissolved in a solvent. Suitable solvents may include water; an alcohol, including methanol, n-propanol, isopropanol, n-butanol, sec-butanol, or tert-butanol, a pentanol, and a hexanol; an ether, including dimethyl ether, diethyl ether, dipropyl ether, dibutyl ether, dimethoxyethane, bis(2-methoxyethyl) ether, triethylene glycol dimethyl ether, tetraethylene glycol dimethyl ether, and dioxane; tetrahydrofuran; or acetonitrile.

In some embodiments, the reducing agent treatment converts water and/or acid soluble oxides on the surface of the absorber layer and capping layer into oxides that are insoluble in water and/or acid, as explained above with respect to the second plasma etch.

A wet cleaning operation is subsequently performed on the photomask 75 of FIG. 9B or FIG. 10. In some embodiments, the wet cleaning operation includes applying an aqueous solution of sulfuric acid and hydrogen peroxide to the photomask 75. In some embodiments, the cleaning solution is a piranha solution. The piranha solution is useful for removing organic contaminants from the photomask. In other embodiments, the wet cleaning solution comprises a mixture of carbon dioxide or hydrogen dissolved in water, or deionized water.

For example, in some embodiments, the application of the reducing agent, followed by wet cleaning effectively removes tin contaminants as shown in reactions below: The first reaction caused by the reducing agent removes a passivation layer to expose elemental tin, as follows:

SnO+SnO₂→Sn

and then the sulfuric acid/peroxide wet clean oxidizes and dissolves the elemental tin, as follows:

Sn→Sn²⁺.

In some embodiments, applying the reducing agent and a subsequent wet cleaning operation provides for the removal or organic contaminants; metallic contaminants including Cr, Ta, Al, Fe, Na, Mg, and Ru; and non-metallic contaminants, including Si and S. In some embodiments, there is less than 0.1 nm shift in the critical dimension after performing the reducing agent treatment followed by the wet cleaning operation.

In some embodiments, defects are detected by a laser scanning tool that incorporates optics and image processing methods to inspect photomask defects such as pattern abnormality or particles. In some embodiments, the type of defect is analyzed by energy dispersive x-ray (EDX) to determine the elemental composition of material. In some embodiments, critical dimension (CD) measurement is performed by a CD scanning electron microscope metrology tool which measures the line and/or space of a patterned mask.

After the wet cleaning operation, the thin oxide layer 60 remains substantially intact, as shown in FIG. 11. The insoluble oxides formed during the second plasma etching operation (or plasma treatment) protect the thin oxide layer 60 from being degraded by the wet cleaning operation because the thin oxide layer is substantially insoluble in aqueous and acidic cleaning solutions, such as the piranha solution. In some embodiments, the thickness of the thin oxide layer T3 after the wet cleaning operation ranges from about 0.5 nm to about 5 nm in some embodiments. In other embodiments, the thin oxide layer 60 has a thickness T3 ranging from about 2 nm to about 3.5 nm. In some embodiments, a ratio of a thickness T3 of the oxide layer after the wet cleaning operation to a thickness T2 of the oxide layer before the wet cleaning operation ranges from 0.8 to 1.0. In some embodiments, the width W3 of the trench after the wet cleaning operation ranges from about from about 291 nm to about 995 nm in some embodiments, and about 295 nm to about 990 nm in other embodiments. If the thickness T3 of thin oxide layer 60 is less than the disclosed range there may be insufficient protection of the absorber layer pattern and the capping layer. If the thickness T3 of the thin oxide layer 60 is greater than the disclosed range there may be loss of control of fine pattern detail and pattern resolution.

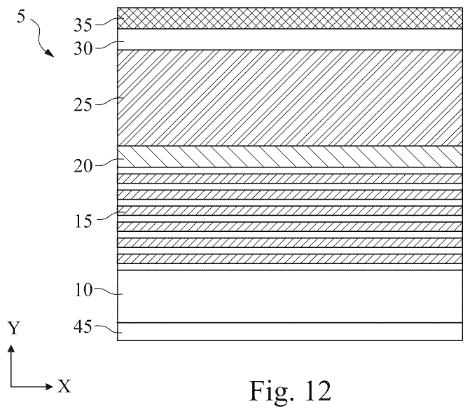

FIGS. 12-23 schematically illustrate another embodiment of a method of fabricating an EUV photomask for use in EUV lithography. It is understood that additional operations can be provided before, during, and after the processes shown by FIGS. 12-23, and some of the operations described below can be replaced or eliminated for additional embodiments of the disclosed methods. The order of the operations/processes may be interchangeable.

A first photoresist layer 35 is formed over a first hard mask layer 30 of an EUV photomask blank 5 as shown in FIG. 12. The photomask blank 5 is the same as the photomask blank shown in FIG. 4 in some embodiments. In other embodiments, the photomask blank includes one or more of a second hard mask layer 32, an oxide layer 27, an intermediate layer 22, and a substrate protection layer 12, as disclosed herein in reference to FIGS. 3D, 3E, and the written description of the embodiments of FIGS. 4-11. Before the first photoresist layer 35 is formed, the EUV photomask blank is subject to inspection in some embodiments.

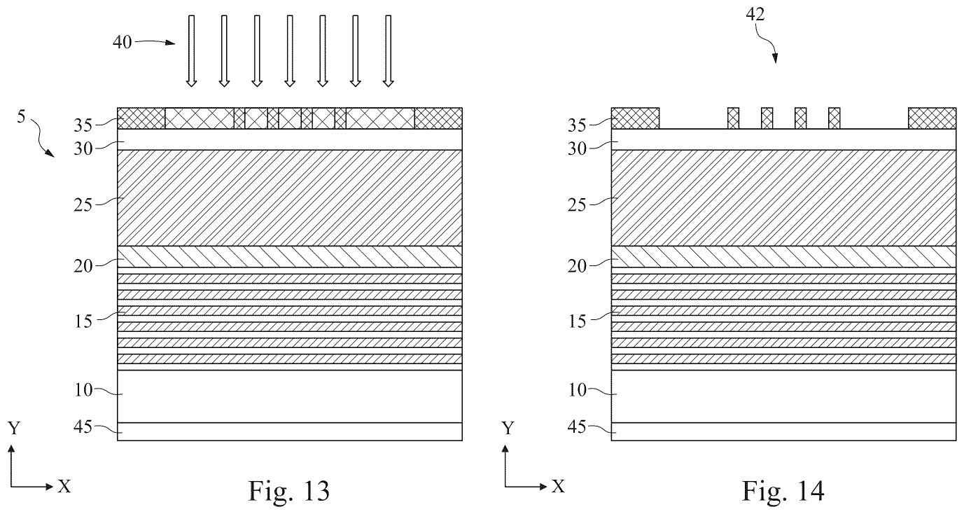

The first photoresist layer 35 is patterned to form a pattern exposing the hard mask layer 30 in some embodiments. The photoresist layer 35 is patterned by selectively exposing the photoresist layer 35 to actinic radiation 40, as shown in FIG. 13, and then developing the selectively exposed photoresist layer 35 is to form a pattern 42, as shown in FIG. 14. In some embodiments, the actinic radiation 40 is an electron beam or an ion beam. In the embodiment shown in FIGS. 13 and 14, the photoresist layer is made of a positive-tone photoresist wherein the portion of the photoresist exposed to actinic radiation is removed during development. In other embodiments, the photoresist is a negative-tone photoresist where the portion of the photoresist layer not exposed to actinic radiation is removed during development. In some embodiments, the pattern 42 includes features having narrower and wider spaced features. In some embodiments, the 42 corresponds to a pattern of semiconductor device features for which the EUV photomask will be used to form in subsequent operations. In some embodiments, the thickness of the first photoresist layer 35 disposed on the hard mask layer 32 ranges from about 500 nm to about 1000 nm.

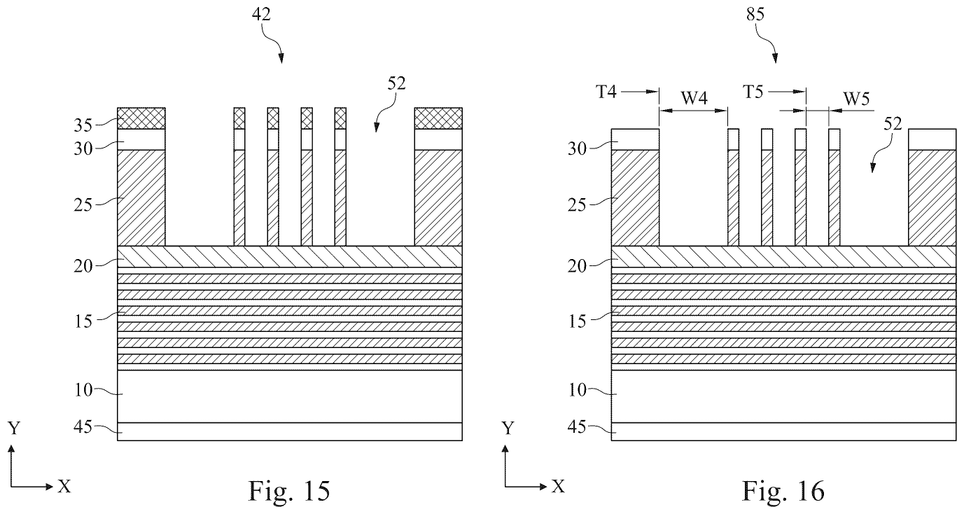

Next, the pattern 42 in the first photoresist layer 35 is extended into the hard mask layer 30 and the absorber layer 25 forming a pattern 52 in the absorber layer exposing the capping layer 20, as shown in FIG. 15. The pattern 42 extended into the hard mask layer 30 is formed by etching, in some embodiments, using a suitable wet or dry etchant that is selective to the first hard mask layer 30. In some embodiments, a plasma dry etching operation using a chlorine containing gas (e.g., Cl₂, HCl, BCl, and CCl₄) and an oxygen containing gas (e.g., O₂) is used to pattern the first hard mask layer 30 and absorber layer 25. In other embodiments, the plasma dry etching operation uses a fluorine containing gas (e.g., a fluorocarbon (CF₄, CHF₃, etc.) and SF₆) to pattern the first hard mask layer 30. In some embodiments, a different etchant is used to etch the first hard mask layer 30 and the absorber layer 25.

After the pattern 52 is formed in the absorber layer is formed, the first photoresist layer 35 is removed by a photoresist stripper to expose the upper surface of the first hard mask layer 30, as shown in FIG. 16. In some embodiments, the photoresist layer 35 is removed after etching the opening in the first hard mask layer 30 and before extending the opening through the absorber layer 25.

In some embodiments, the absorber layer pattern 52 has wide widths W4 separating pattern features ranging from about 100 nm to about 300 nm, and narrow widths W5 separating other pattern features ranging from about 30 nm to about 100 nm. In some embodiments, the narrow widths W5 range from about 40 nm to about 80 nm. In some embodiments, after forming the pattern by etching there is no measurable oxide layer on the sidewalls of the trench. In other words, the pattern features have a sidewall oxide layer having a thickness T4, T5 of about 0 nm.

In some embodiments, the hard mask layer includes a first hard mask layer 30 and a second hard mask layer 32, as described herein. The materials for the two hard mask layers, 30, 32 may be any of the materials disclosed herein for the first hard mask layer 30 and the second hard mask layer 32. In addition, the first and second hard mask layers 30, 32 may be etched to extend the pattern 42 according to the etching operations disclosed herein for the first and second hard mask layers 30, 32.

In embodiments including the oxide layer 27 over the absorber layer 25, the oxide layer 27 is subsequently etched to expose the absorber layer, as disclosed herein in reference to the embodiment of FIGS. 4-11. Then, the pattern 42 in the first hard mask layer 30 is extended into the absorber layer 25 forming the pattern 52 exposing portions of the capping layer 20 or the intermediate layer 22 in embodiments including the intermediate layer.

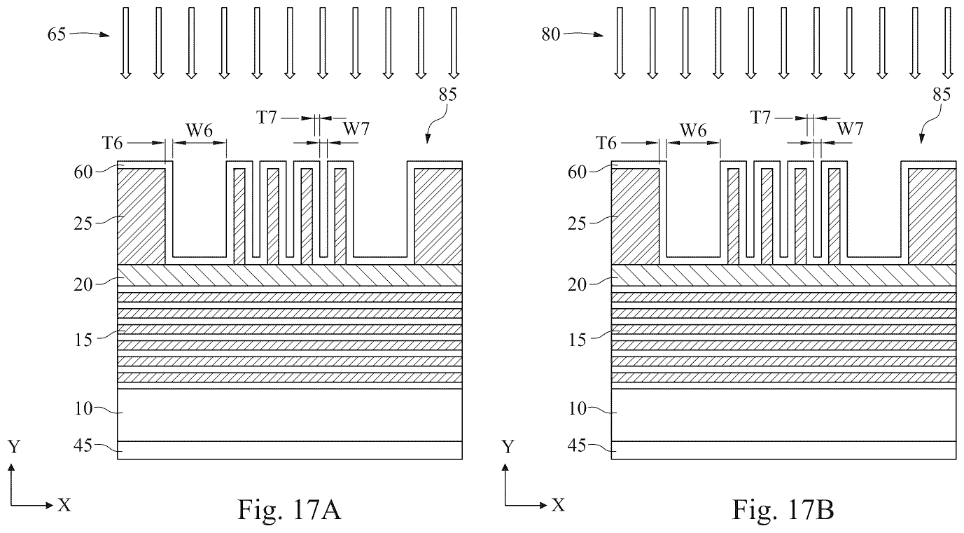

Then, the first hard mask layer 30 is removed to form a photomask 85. In some embodiments, the etching is wet etching and/or dry etching. In some embodiments, the exposed portions of the intermediate layer, if present, is also removed. After removing the first hard mask layer in some embodiments, a first plasma treatment including a first plasma 65, is performed on the photomask 85, as shown in FIG. 17A. In some embodiments, the first plasma 65 includes a mixture of oxygen and water vapor. In some embodiments, the first plasma treatment is an inductively coupled plasma treatment. The oxygen plasma removes organic contaminants from the surface of the photomask 85. In oxygen/water vapor plasma cleaning, water vapor can be used as a process gas alongside oxygen to enhance the cleaning process. The water vapor can be used to break down organic contaminants, improve the removal of certain materials, and/or introduce a higher level of hydrophilicity to a surface. The parameters of the oxygen/water vapor plasma treatment (first plasma treatment) are disclosed herein with reference to FIG. 9A.

The oxygen/water vapor plasma forms a thin oxide layer 60 on the surface of the absorber layer 25 and the exposed portions of the capping layer 20. The thin oxide layer 60 has a thickness T6 on the sidewalls of widely spaced features and a thickness T7 on the sidewalls of narrowly spaced features ranging from about 1 nm to about 5 nm in some embodiments. In other embodiments, the thin oxide layer 60 has a thickness T6, T7 ranging from about 2.5 nm to about 3.5 nm. In some embodiments, the thickness T6, T7 of the thin oxide layer is about the same over the widely spaced features and the narrowly spaced features. The formation of the thin oxide layer 60 decreases the width of the space between pattern features by about 2 nm to about 10 nm, in some embodiments, and by about 5 nm to about 7 nm in other embodiments. In some embodiments, the width W6 between the widely spaced features of the pattern 52 after the first hard mask removal ranges from about 90 nm to about 298 nm in some embodiments, and about 95 nm to about 290 nm in other embodiments. In some embodiments, the width W7 between the narrowly spaced features of the pattern 52 after the first hard mask removal ranges from about 20 nm to about 98 nm in some embodiments, and about 25 nm to about 90 nm in other embodiments. If the thickness T6, T7 of thin oxide layer 60 is less than the disclosed range there may be insufficient protection of the absorber layer pattern and the capping layer. If the thickness T6, T7 of the thin oxide layer 60 is greater than the disclosed range there may be loss of control of fine pattern detail and pattern resolution.

After the first plasma treatment, the processing chamber where the first hard mask layer is removed is purged for about 10 s to about 180 s with a gas mixture of hydrogen and an inert gas, such as helium, neon, argon, nitrogen, and combinations thereof. After the purging the processing chamber, the photomask 85 is subjected to a second plasma treatment using a plasma 80 formed from a mixture of hydrogen and an inert gas, as shown in FIG. 17B. In some embodiments, the plasma 80 is an inductively coupled plasma. In some embodiments, the concentration of hydrogen in the inert gas ranges from about 0.5 mol. % to about 10 mol. %, and from about 1 mol. % to about 5 mol. % in other embodiments. The inert gas may be selected from helium, neon, argon, nitrogen, and combinations thereof. In some embodiments, the inert gas is helium. In some embodiments, the first and second plasma treatments are performed in the same processing chamber. In other embodiments, the first and second plasma treatments are performed in different processing chambers. Concentrations of hydrogen below the disclosed ranges may result in insufficient protection of the oxide layer, and at concentrations of hydrogen above the disclosed ranges there may be insignificant improvement in the protection of the oxide layer. The parameters of the hydrogen/inert gas plasma treatment (second plasma treatment) are disclosed herein with reference to FIG. 9B.

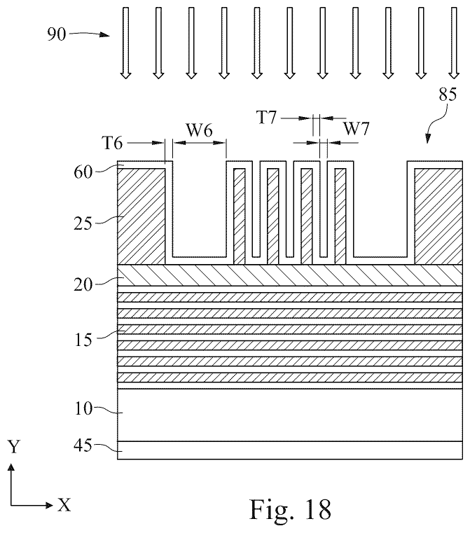

In some embodiments, the first stage of the cleaning process includes applying a reducing agent 90 to photomask 85 after the first hard mask layer 30 is removed, as shown in FIG. 18, and discussed herein in reference to FIG. 10.

As explained herein, in some embodiments, the reducing agent treatment or the second plasma treatment converts water and/or acid soluble oxides on the surface of the absorber layer and capping layer into oxides that are insoluble in water and/or acid. A wet cleaning operation is subsequently performed on the photomask 85 shown in FIGS. 17B and 18, as disclosed herein in reference to the embodiment of FIGS. 4-11.

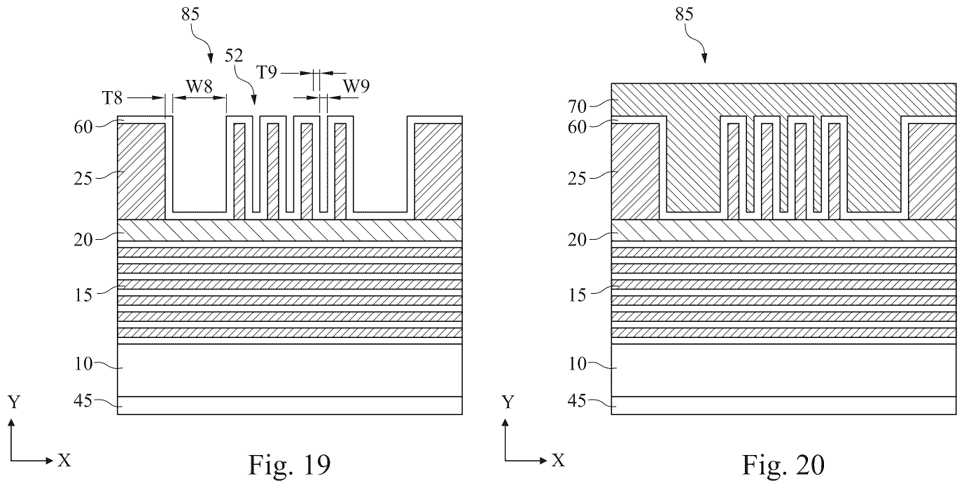

After the wet cleaning operation, the thin oxide layer 60 remains substantially intact, as shown in FIG. 19. The insoluble oxides formed during the second plasma treatment protect the thin oxide layer 60 from being degraded by the wet cleaning operation because the thin oxide layer is substantially insoluble in aqueous and acidic cleaning solutions, such as the piranha solution. In some embodiments, the thickness of the thin oxide layer T8, T9 after the wet cleaning operation ranges from about 0.5 nm to about 5 nm in some embodiments. In other embodiments, the thin oxide layer 60 has a thickness T8, T9 ranging from about 2 nm to about 3.5 nm. In some embodiments, a ratio of a thickness T8, T9 of the oxide layer after the wet cleaning operation to a thickness T6, T7 of the oxide layer before the wet cleaning operation ranges from 0.8 to 1.0. In some embodiments, the width W8 between the widely spaced features of the pattern 52 after the wet cleaning operation ranges from about 91 nm to about 298 nm in some embodiments, and about 95 nm to about 290 nm in other embodiments. In some embodiments, the width W9 between the narrowly spaced features of the pattern 52 after the wet cleaning operation ranges from about 21 nm to about 98 nm in some embodiments, and about 25 nm to about 90 nm in other embodiments. If the thickness T8, T9 of thin oxide layer 60 is less than the disclosed range there may be insufficient protection of the absorber layer pattern and the capping layer. If the thickness T8, T9 of the thin oxide layer 60 is greater than the disclosed range there may be loss of control of fine pattern detail and pattern resolution.

In some embodiments, a ratio of a thickness T8, T9 of the oxide layer 60 to a distance W9 separating adjacent features in the pattern 52 formed in the absorber layer ranges from about 0.005 to about 0.24, and in other embodiments the ratio ranges from about 0.01 to about 0.1. At oxide thickness/separation distances between adjacent pattern features outside the disclosed ranges there may be insufficient protection of the oxide layer or insufficient mask pattern resolution.

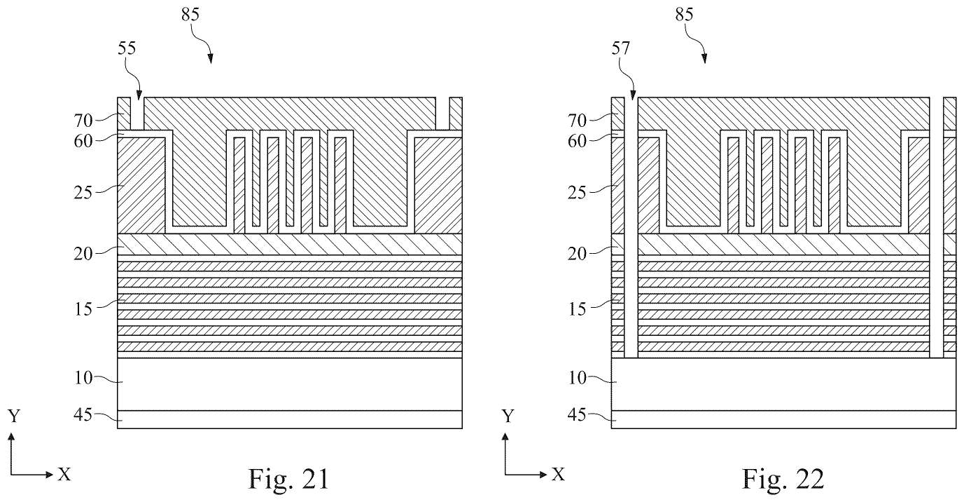

In some embodiments, a black border is formed in the periphery of the photomask surrounding the patterned absorber layer. As shown in FIG. 20, a second photoresist layer 70 is formed over the absorber layer 25 and thin oxide layer 60 filling the pattern 52 in the absorber layer 25. The second photoresist layer 70 is selectively exposed to actinic radiation such as an electron beam, ion beam, or UV radiation. The selectively exposed second photoresist layer 70 is developed to form a pattern 55 in the second photoresist layer 70 as shown in FIG. 21. The pattern 55 corresponds to a black border surrounding the circuit pattern. A black border is a frame shape area created by removing all the layers on the EUV photomask in the region around a circuit pattern area. The black border pattern prevents exposure of adjacent fields when printing an EUV photomask on a wafer. The width of the black border ranges from about 1 mm to about 5 mm in some embodiments.

Next, the pattern 55 in the second photoresist layer 70 is extended into the absorber layer 25, the capping layer 20, and the multilayer 15 forming a pattern 57 exposing portions of the substrate 10, in some embodiments, as shown in FIG. 22. The pattern 57 can be formed by etching using one or more suitable wet or dry etchants that are selective to each of the layers that are etched. In some embodiments, plasma dry etching is used.

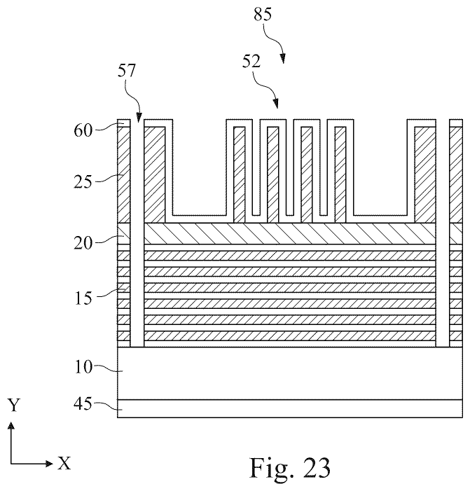

Then, the second photoresist layer 70 is removed by a suitable photoresist stripper to expose the upper surface of the thin oxide layer 60 to form a photomask 75 with circuit patterns 52 and the black border pattern 57, as shown in FIG. 23.

The black border may also be formed in the photomask formed in the embodiment of FIGS. 4-11. In addition, the black border may be formed in photomasks including one or more of the oxide layer 27, intermediate layer 22, and substrate protection layer 12.

Embodiments of the present disclosure provide a 95% to 100% organic contaminant removing efficiency, while maintaining high reflectivity of the EUV photomask 75, 85. For example, in some embodiments, the photomask has less than 0.2% loss in reflectivity/10 cleaning cycles. In some embodiments, EUV photomasks 75, 85 according to the present disclosure have a 2% increase in initial average reflectivity than EUV photomasks manufactured by prior methods. In some embodiments, the photomasks 75, 85 have a mean extreme ultraviolet radiation reflectivity of 65.1±1%. The mean extreme ultraviolet radiation reflectivity is determined by averaging the reflectivity measured at 25 locations across the mask.

The effect of the second plasma treatment can be detected in the photomasks 75, 85 by using time-of-flight secondary ion mass spectrometry (ToF-SIMS). ToF-SIMS analysis of photomasks manufactured according to embodiments of this disclosure show up to a two-fold hydrogen concentration increase at the ruthenium and silicon surface and also show up to a three-fold oxygen concentration decrease at the ruthenium and silicon surface over photomasks manufactured by prior methods. Notably, the presence of hydrogen observed in 1^{st} silicon region of multilayer is due to plasma penetration, which is a phenomenon that occurs during the interaction between plasma and a metal surface. Plasma penetration depth varies across materials. In this embodiment, hydrogen radicals penetrate across ruthenium layer to surface of silicon layer.

In some embodiments, a critical dimension (CD) shift/nm in the pattern of the photomasks manufactured according to the present disclosure is observed to be about 0.07±0.01 for both positive-tone chemically amplified photoresist (PCAR) and negative-tone chemically amplified photoresist (NCAR) during front end processing and the CD shift/nm for both PCAR and NCAR photoresists is ≤0.04 at the backend processing The difference in CD shift/nm observed at process and backend is due to the difference in sulfuric acid content within sulfuric peroxide mixture whereby higher sulfuric acid content will exhibit smaller CD shift/nm. For example, in the front end processing, the ratio of H₂SO₄:H₂O₂ is about 10:1 in some embodiments, while the ratio of H₂SO₄:H₂O₂ in the backend processing is greater than about 10:1. In some embodiments, the ratio in the backend processing is about 19:1. The CD measurement is performed by a CD scanning electron microscope metrology tool which measures both the line and/or space of a patterned mask.

The ruthenium durability of the capping layer 20 was determined by subjecting the masks 75, 85 to an etching gas, such as xenon difluoride, for a series of etching cycle of about 3 to 4 minutes at an etching rate of about 0.1 to about 0.3 nm/cycle, with a pause of about 30 s to 60 s between etching cycles. Analysis of the ruthenium durability of the capping layers of masks 75, 85 manufactured according to the present disclosure show a significant improvement in durability over masks manufactured by prior methods.

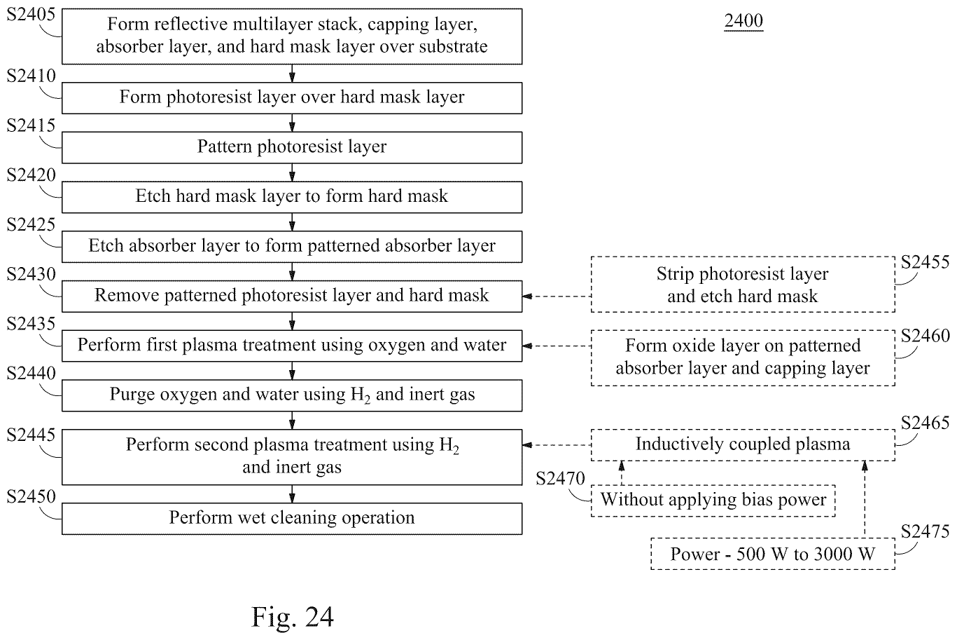

FIG. 24 shows a flow chart of a method 2400 of manufacturing an EUV mask according to embodiments of the present disclosure. In operation S2405, a reflective multilayer stack 15, a capping layer 20, an absorber layer 25, and a hard mask layer 30 is formed over a substrate 10 in sequence. In operation S2410, a photoresist layer 35 is formed over the hard mask layer. The photoresist layer 35 is patterned in operation S2415, and the hard mask layer 30 is etched to form a hard mask in operation S2420. The absorber layer 25 is etched in operation S2425 to form a patterned absorber layer using the hard mask as an etching mask in some embodiments. In operation S2430, the patterned photoresist layer and the hard mask are removed. In some embodiments, the patterned photoresist layer is stripped using a suitable photoresist stripper and the hard mask is removed by etching in operation S2455. A first plasma treatment is performed using a plasma of a mixture of oxygen and water in operation S2435. In some embodiments, the water is water vapor. In some embodiments, the first plasma treatment forms an oxide layer on the absorber layer and the capping layers in operation S2460. After the first plasma treatment, the oxygen and water in the processing chamber is purged using a mixture of hydrogen and an inert gas in operation S2440. In some embodiments, a stream of hydrogen and inert gas is flowed through the processing chamber. After purging the processing chamber, a second plasma treatment is performed using a mixture of hydrogen and an inert gas in operation S2445. In some embodiments, the inert gas used in the second plasma treatment is the same as the inert gas used in the purging operation S2440. In some embodiments, the inert gas is helium. In some embodiments, the second plasma treatment is an inductively coupled plasma treatment, as in operation S2465. In some embodiments, the inductively coupled plasma treatment is performed without applying a bias power, as in operation S2470. In some embodiments, the source power for the inductively coupled plasma ranges from 500 W to 3000 W, as in operation S2475. After performing the second plasma treatment, a wet cleaning operation is performed in operation S2450.

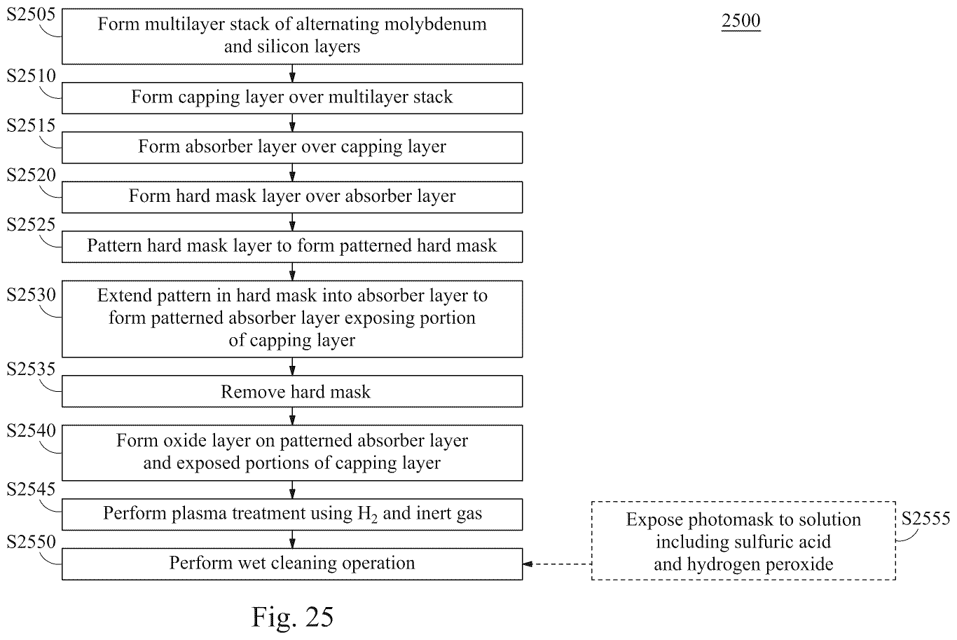

FIG. 25 shows a flow chart of a method 2500 of manufacturing a photomask according to embodiments of the present disclosure. In operation S2505, a multilayer stack 15 of alternating molybdenum and silicon layers is formed. A capping layer 20 is formed over the multilayer stack 15 in operation S2510. Then, an absorber layer 25 is formed over the capping layer 20 in operation S2515, and a hard mask layer 30 is formed over the capping layer 20 in operation S2520. In operation S2525, the hard mask layer 30 is patterned to form a patterned hard mask. In operation S2530, the pattern 41, 42 in the hard mask 30 is extended into the absorber layer 25 to form a patterned absorber layer 25 exposing a portion of the capping layer 20. Next, the hard mask is removed in operation S2535. Then, in operation S2540, an oxide layer is formed on the patterned absorber layer 25 and exposed portions of the capping layer 20. A plasma treatment is performed using a mixture of hydrogen and an inert gas in operation S2545. After the plasma treatment, a wet cleaning operation is performed in operation S2550. The photomask 75, 85 is exposed to a solution including sulfuric acid and hydrogen peroxide in some embodiments in operation S2555.

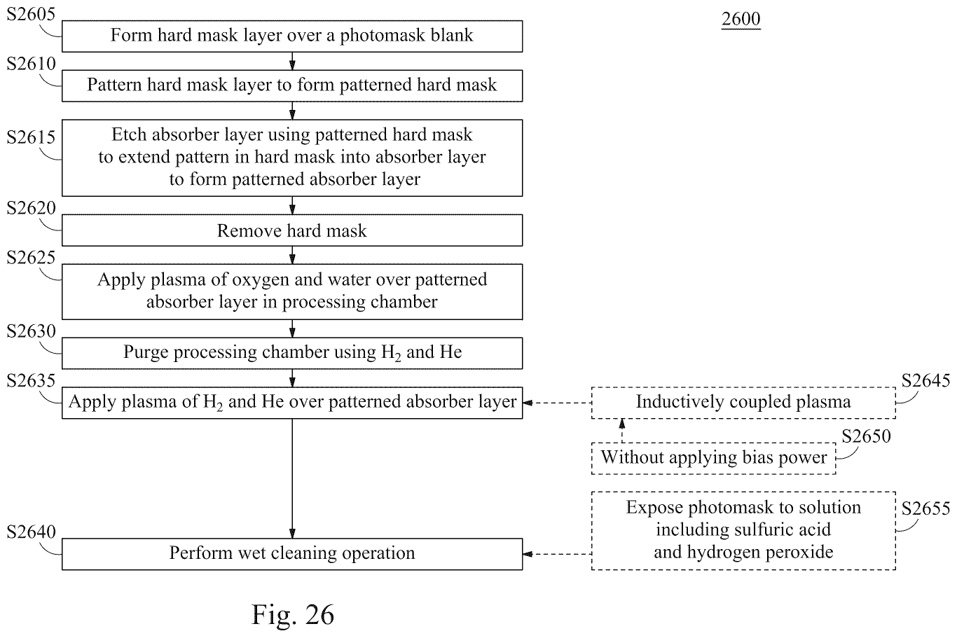

FIG. 26 shows a flow chart of a method 2600 of manufacturing a photomask according to embodiments of the present disclosure. In operation S2605, a hard mask layer 30 is formed over a photomask blank 5. In some embodiments, the photomask blank includes: a multilayer stack 15 of alternating first and second layers disposed over a substrate 10, wherein the first and second layers are made of different materials; a capping layer 20 disposed over the multilayer stack 15, wherein the capping layer is made of a different material than the first and second layers; and an absorber layer 25 disposed over the capping layer 20, wherein the absorber layer 25 is made of a different material than the capping layer 20. In operation S2610, the hard mask layer 30 is patterned to form a patterned hard mask. The absorber layer 25 is etched using the patterned hard mask 30 to extend the pattern 41, 42 in the hard mask into the absorber layer to form a patterned absorber layer 25 in operation S2615. Then, in operation S2620, the hard mask is removed. A first plasma 65 of oxygen and water is applied over the patterned absorber layer 25 in a processing chamber in operation S2625. After applying the first plasma 65, the processing chamber is purged using a mixture of hydrogen and helium in operation S2630. After purging the processing chamber, a second plasma 80 of a mixture of hydrogen and helium is applied over the patterned absorber layer 25 in operation S2635. In some embodiments, the second plasma 80 is an inductively coupled plasma, as in operation S2645. In some embodiments, the inductively coupled plasma 80 is applied without applying a bias power, as in operation S2650. After applying the second plasma 80, a wet cleaning operation S2640 is performed on the photomask 75, 85. In some embodiments, the wet cleaning operation S2640 includes exposing the photomask 75, 85 to a solution including sulfuric acid and hydrogen peroxide, as in operation S2655.

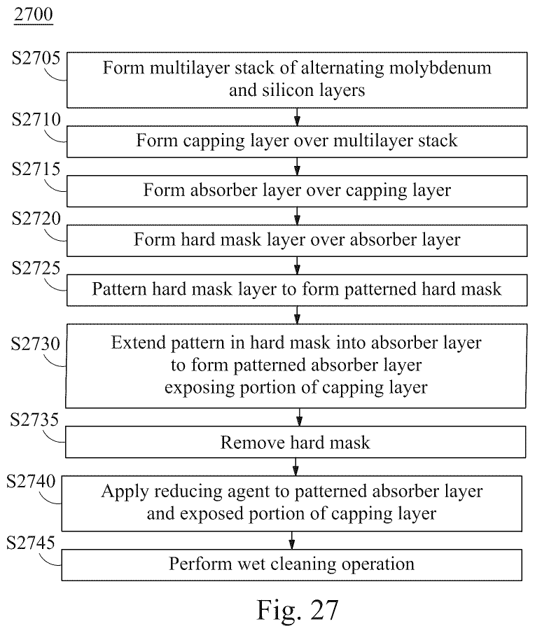

FIG. 27 shows a flow chart of a method 2700 of manufacturing a photomask according to embodiments of the present disclosure. In operation S2705, a multilayer stack 15 of alternating molybdenum and silicon layers is formed. A capping layer 20 is formed over the multilayer stack 15 in operation S2710. Then, an absorber layer 25 is formed over the capping layer 20 in operation S2715, and a hard mask layer 30 is formed over the capping layer 20 in operation S2720. In operation S2725, the hard mask layer 30 is patterned to form a patterned hard mask. In operation S2730, the pattern 41, 42 in the hard mask 30 is extended into the absorber layer 25 to form a patterned absorber layer 25 exposing a portion of the capping layer 20. Next, the hard mask is removed in operation S2735. Then, in operation S2540, a reducing agent 90 is applied to the patterned absorber layer 25 and the exposed portion of the capping layer 30. The reducing agent includes at least one of a hydrogen plasma, hydrogen gas, carbon monoxide, sodium borohydride, lithium aluminum hydride, hydrazine, hydrogen peroxide, sulfur dioxide, sodium dithionite, or ascorbic acid. A wet cleaning operation is then performed in operation S2745.

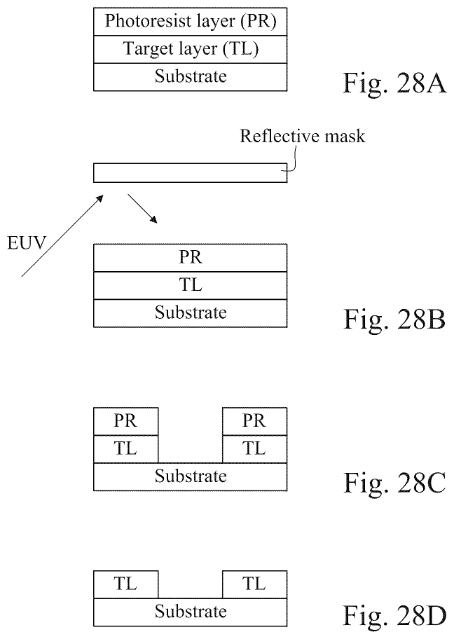

FIGS. 28A, 28B, 28C, and 28D show a sequential manufacturing operation of the method of making a semiconductor device in accordance with embodiments of present disclosure. A semiconductor substrate or other suitable substrate to be patterned to form an integrated circuit thereon is provided. In some embodiments, the semiconductor substrate includes silicon. Alternatively or additionally, the semiconductor substrate includes germanium, silicon germanium or other suitable semiconductor material, such as a Group III-V semiconductor material.

As shown in FIG. 28A, a target layer (TL) to be patterned is formed over the semiconductor substrate. In certain embodiments, the target layer is the semiconductor substrate. In some embodiments, the target layer includes a conductive layer, such as a metallic layer or a polysilicon layer; a dielectric layer, such as silicon oxide, silicon nitride, SiON, SiOC, SiOCN, SiCN, hafnium oxide, or aluminum oxide; or a semiconductor layer, such as an epitaxially formed semiconductor layer. In some embodiments, the target layer is formed over an underlying structure, such as isolation structures, transistors or wirings. A photoresist layer PR is formed over the target layer TL, as shown in FIG. 28A. The photoresist layer is sensitive to the radiation from the exposing source during a subsequent photolithography exposing process. In the present embodiment, the photoresist layer is sensitive to EUV light used in the photolithography exposing process. The photoresist layer may be formed over the target layer by spin-on coating or other suitable technique. The coated photoresist layer may be further baked to drive out solvent in the photoresist layer.

The photoresist layer is subsequently patterned using an EUV reflective mask manufactured according to a method disclosed herein, as shown in FIG. 28B. The patterning of the photoresist layer includes performing a photolithography exposing process by an EUV exposing system using the EUV mask. During the exposing process, the integrated circuit (IC) design pattern defined on the EUV mask is imaged to the photoresist layer to form a latent pattern thereon.

The patterning of the photoresist layer further includes developing the exposed photoresist layer to form a patterned photoresist layer having one or more openings, as shown in FIG. 28C. In one embodiment where the photoresist layer is a positive tone photoresist layer, the exposed portions of the photoresist layer are removed during the developing process. In other embodiments, the photoresist layer is a negative tone photoresist layer, and the unexposed portions of the photoresist layer are removed during the developing process. The patterning of the photoresist layer may further include other process steps, such as various baking steps at different stages. For example, a post-exposure-baking (PEB) process may be implemented after the photolithography exposing process and before the developing process.

As shown in FIG. 28C, the target layer TL is patterned using the patterned photoresist layer as an etching mask. In some embodiments, the patterning the target layer includes applying an etching process to the target layer using the patterned photoresist layer as an etching mask. The portions of the target layer exposed within the openings of the patterned photoresist layer are etched while the remaining portions are protected from etching. Further, the patterned photoresist layer may be removed by wet stripping or plasma ashing, as shown in FIG. 28D.

Embodiments of the present disclosure prevent critical dimension loss during photomask fabrication and cleaning operations. Embodiments of the disclosure minimize material, such as chromium and ruthenium, loss during mask cleaning and simultaneously remove hydrocarbon contaminants providing improved EUV reflectivity. Embodiments of the disclosure provide a 2-fold window expansion in the photomask patterning process, extend mask lifetime, improve hydrocarbon defect removal, and improve and control EUV reflectivity during semiconductor device manufacturing operations. Embodiments of the present disclosure further provide increased capping layer durability upon exposure to etching cycles. Embodiments of the present disclosure also prevent watermark defects caused by the cleaning process. Embodiments of the present disclosure provide 95% to 100% organic contaminant removing efficiency. Embodiments of the present disclosure maintain high reflectivity of the EUV photomask. For example, in some embodiments, the photomask has less than 0.2% loss in reflectivity/10 cleaning cycles. In some embodiments, EUV photomasks according to the present disclosure have a 2% increase in initial average reflectivity than EUV photomasks manufactured by prior methods. In some embodiments, the photomasks have a mean extreme ultraviolet radiation reflectivity of 65.1±1%. In some embodiments, there is no significant critical dimension changes (e.g.—≤0.3 nm) after 2-4 consecutive cycles of first and second plasma treatments. In some embodiments, there is no significant damage to ruthenium capping layers. In some embodiments, applying the reducing agent and a subsequent wet cleaning operation provides for the removal or organic contaminants; metallic contaminants including Cr, Ta, Al, Fe, Na, Mg, and Ru; and non-metallic contaminants, including Si and S.

In some embodiments, the methods disclosed herein provide improved resolution of the circuit patterns formed in absorber layer. Embodiments of the disclosure provide improved mask critical dimension (CD) uniformity, and prevent mask induced CD profile decay.

It will be understood that not all advantages have been necessarily discussed herein, no particular advantage is required for all embodiments or examples, and other embodiments or examples may offer different advantages.

According to an embodiment of the disclosure, a method of manufacturing an extreme ultraviolet mask includes forming a reflective multilayer stack, a capping layer, an absorber layer, and a hard mask layer over a substrate in sequence. A photoresist layer is formed over the hard mask layer, and the photoresist layer is patterned. The hard mask layer is etched to form a hard mask. The absorber layer is etched to form a patterned absorber layer. The patterned photoresist layer and the hard mask are removed. A first plasma treatment is performed using a plasma formed from a mixture of oxygen and water. The plasma is purged using a mixture of H₂ and an inert gas. A second plasma treatment is performed using a plasma formed from a mixture of H₂ and an inert gas; and a wet cleaning operation is performed. In an embodiment, the removing the patterned photoresist layer and the hard mask includes stripping the photoresist layer and etching the hard mask. In an embodiment, the wet cleaning operation is performed after performing the second plasma treatment. In an embodiment, the second plasma treatment is an inductively coupled plasma treatment. In an embodiment, the inductively coupled plasma treatment is performed without applying bias power. In an embodiment, a power applied during the second plasma treatment ranges from 500 W to 4000 W. In an embodiment, a concentration of H₂ in the mixture of H₂ and inert gas ranges from 1 mol. % to 5 mol. %. In an embodiment, an oxide layer is formed on the patterned absorber layer and capping layer during the first plasma treatment. In an embodiment, a ratio of a thickness of the oxide layer after the wet cleaning operation to a thickness of the oxide layer before the wet cleaning operation ranges from 0.8 to 1.0.

According to another embodiment of the disclosure, a method of manufacturing a photomask includes forming a multilayer stack of alternating molybdenum and silicon layers over a substrate. A capping layer is formed over the multilayer stack and an absorber layer is formed over the capping layer. A hard mask layer over the absorber layer, and the hard mask layer is patterned to form a patterned hard mask. The pattern in the hard mask is extended into the absorber layer to form a patterned absorber layer exposing a portion of the capping layer. The hard mask is removed. An oxide layer is formed on the patterned absorber layer and exposed portions of the capping layer. A plasma treatment is performed using a plasma formed from a mixture of H₂ and an inert gas, and a wet cleaning operation is performed. In an embodiment, the capping layer includes ruthenium or a ruthenium alloy. In an embodiment, the absorber layer includes chromium or a chromium compound. In an embodiment, the wet cleaning operation is performed after the plasma treatment. In an embodiment, the wet cleaning operation includes exposing the photomask to a solution including sulfuric acid and hydrogen peroxide. In an embodiment, a concentration of H₂ in the mixture used to form the plasma ranges from 1 mol. % to 5 mol. %.

Another embodiment of the disclosure is a method of manufacturing a photomask, including forming a hard mask layer over a photomask blank. The photomask blank includes a multilayer stack of alternating first and second layers disposed over a substrate, wherein the first and second layers are made of different materials; a capping layer disposed over the multilayer stack, wherein the capping layer is made of a different material than the first and second layers; and an absorber layer disposed over the capping layer, wherein the absorber layer is made of a different material than the capping layer. The hard mask layer is patterned to form a patterned hard mask. The absorber layer is etched using the patterned hard mask as an etching mask to extend the pattern in the hard mask into the absorber layer to form a patterned absorber layer. The patterned absorber layer exposes a portion of the capping layer. The hard mask is removed. A first plasma formed from a mixture of oxygen and water is applied over the patterned absorber layer in a processing chamber. The processing chamber is purged using a mixture of H₂ and He after applying the first plasma. A second plasma formed from a mixture of H₂ and He is applied over the patterned absorber layer after purging the processing chamber. A wet cleaning operation is performed on the photomask after applying the second plasma. In an embodiment, the second plasma is an inductively coupled plasma. In an embodiment, the inductively coupled plasma treatment is performed without applying bias power. In an embodiment, the wet cleaning operation includes exposing the photomask to a solution including sulfuric acid and hydrogen peroxide. In an embodiment, a concentration of H₂ in the mixture to form the second plasma ranges from 1 mol. % to 5 mol. %.

Another embodiment of the disclosure is a method of manufacturing a photomask including forming a multilayer stack of alternating molybdenum and silicon layers over a substrate. A capping layer is formed over the multilayer stack. An absorber layer is formed over the capping layer. A hard mask layer is formed over the absorber layer. The hard mask layer is patterned to form a patterned hard mask. The pattern in the hard mask is extended into the absorber layer to form a patterned absorber layer exposing a portion of the capping layer, and the hard mask is removed. After removing the hard mask, a reducing agent is applied to the patterned absorber layer and exposed portion of the capping layer, and a wet cleaning operation is performed. In an embodiment, the reducing agent includes at least one of a hydrogen plasma, hydrogen gas, carbon monoxide, sodium borohydride, lithium aluminum hydride, hydrazine, hydrogen peroxide, sulfur dioxide, sodium dithionite, or ascorbic acid. In an embodiment, the reducing agent is dissolved in a solvent or an inert gas. In an embodiment, the capping layer includes ruthenium or a ruthenium alloy. In an embodiment, the absorber layer comprises chromium or a chromium compound. In an embodiment, the wet cleaning operation is performed after the applying the reducing agent.

Another embodiment of the disclosure is a reflective photomask, including a reflective multilayer stack disposed over a substrate, wherein the reflective multilayer stack includes a plurality of alternating first layers and second layers. A capping layer is disposed over the reflective multilayer stack, and a patterned absorber layer is disposed over the capping layer. The reflective photomask has a mean extreme ultraviolet radiation reflectivity of 65.1±1%. In an embodiment, the reflective multilayer stack includes 40±1 pairs of first and second layers. In an embodiment, the reflective photomask includes an oxide layer disposed over the patterned absorber layer. In an embodiment, the patterned absorber layer is made of Cr, CrN, CrON, or CrCON. In an embodiment, the capping layer is made of ruthenium, a ruthenium alloy, or a ruthenium-based oxide. In an embodiment, the reflective photomask includes a black border exposing the substrate surrounding a patterned region of the photomask. In an embodiment, the reflective photomask includes an intermediate layer disposed between the capping layer and the patterned absorber layer, wherein the intermediate layer is made of a different material than the capping layer and the patterned absorber layer.

Another embodiment of the disclosure is a reflective photomask including a multilayer stack including a plurality of alternating pairs of a first material layer and a second material layer disposed over a substrate, wherein the first material has a different composition than the second material layer. A capping layer having a different composition than the first material and the second material is disposed over the multilayer stack. An absorber layer having a different composition than the capping layer is disposed over the capping layer, wherein a pattern is formed in the absorber layer. An oxide layer is disposed over the absorber layer. The oxide layer has a thickness ranging from 2 nm to 3.5 nm. In an embodiment, the pattern includes adjacent oxide covered pattern features separated from each other by a distance ranging from 25 nm to 100 nm. In an embodiment, the multilayer stack includes 40±1 pairs of molybdenum and silicon layers. In an embodiment, the absorber layer is made of Cr, CrN, CrON, or CrCON. In an embodiment, the capping layer is made of ruthenium, a ruthenium alloy, or a ruthenium-based oxide. In an embodiment, the reflective photomask includes a trench exposing the substrate surrounding the pattern. In an embodiment, the reflective photomask includes an intermediate layer disposed between the capping layer and the absorber layer, wherein the intermediate layer is made of a different material than the capping layer and the absorber layer.

Another embodiment of the disclosure is a photomask including a multilayer stack including a plurality of alternating pairs of a first layer and a second layer, wherein the first layer is made of a different material than the second layer. A capping layer made of a different material than the first layer and the second layer is disposed over the multilayer stack. An absorber layer made of a different material than the capping layer is disposed over the capping layer, wherein a pattern is formed in the absorber layer. An oxide layer is disposed over the absorber layer. A ratio of a thickness of the oxide layer to a distance separating adjacent features in the pattern formed in the absorber layer ranges from 0.005 to 0.24. In an embodiment, an oxide layer is disposed over top surfaces and sidewalls of the pattern formed in the absorber layer and over portions of the capping layer between pattern features in the absorber layer. In an embodiment, the multilayer stack includes 40±1 pairs of molybdenum and silicon layers. In an embodiment, the absorber layer is made of Cr, CrN, CrON, or CrCON. In an embodiment, the capping layer is made of ruthenium, a ruthenium alloy, or a ruthenium-based oxide. In an embodiment, the photomask includes an intermediate layer disposed between the capping layer and the absorber layer, wherein the intermediate layer is made of a different material than the capping layer and the absorber layer.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing an extreme ultraviolet mask, comprising:
forming a reflective multilayer stack, a capping layer, an absorber layer, and a hard mask layer over a substrate in sequence;
forming a photoresist layer over the hard mask layer;
patterning the photoresist layer;
etching the hard mask layer to form a hard mask;
etching the absorber layer to form a patterned absorber layer;
removing the patterned photoresist layer and the hard mask;
performing a first plasma treatment using a plasma formed from a mixture of oxygen and water;
purging the plasma using a mixture of H₂ and an inert gas;
performing a second plasma treatment using a plasma formed from a mixture of H₂ and an inert gas; and
performing a wet cleaning operation.

2. The method according to claim 1, wherein the removing the patterned photoresist layer and the hard mask comprises stripping the photoresist layer and etching the hard mask.

3. The method according to claim 1, wherein the wet cleaning operation is performed after performing the second plasma treatment.
The method according to claim 1, wherein the second plasma dry treatment is an inductively coupled plasma treatment.

5. The method according to claim 4, wherein the inductively coupled plasma treatment is performed without applying bias power.

6. The method according to claim 4, wherein a power applied during the second plasma treatment ranges from 500 W to 4000 W.

7. The method according to claim 1, wherein a concentration of H₂ in the mixture of H₂ and inert gas ranges from 1 mol. % to 5 mol. %.

8. The method according to claim 1, wherein an oxide layer is formed on the patterned absorber layer and capping layer during the first plasma treatment.

9. The method according to claim 8, wherein a ratio of a thickness of the oxide layer after the wet cleaning operation to a thickness of the oxide layer before the wet cleaning operation ranges from 0.8 to 1.0.

10. A method of manufacturing a photomask, comprising:
forming a multilayer stack of alternating molybdenum and silicon layers over a substrate;
forming a capping layer over the multilayer stack;
forming an absorber layer over the capping layer;
forming a hard mask layer over the absorber layer;
patterning the hard mask layer to form a patterned hard mask;
extending the pattern in the hard mask into the absorber layer to form a patterned absorber layer exposing a portion of the capping layer;
removing the hard mask;
after removing the hard mask, applying a reducing agent to the patterned absorber layer and exposed portion of the capping layer; and
performing a wet cleaning operation.

11. The method according to claim 10, wherein the reducing agent comprises at least one of a hydrogen plasma, hydrogen gas, carbon monoxide, sodium borohydride, lithium aluminum hydride, hydrazine, hydrogen peroxide, sulfur dioxide, sodium dithionite, or ascorbic acid.

12. The method according to claim 11, wherein the reducing agent is dissolved in a solvent or an inert gas.

13. The method according to claim 10, wherein the capping layer comprises ruthenium or a ruthenium alloy.

14. The method according to claim 10, wherein the absorber layer comprises chromium or a chromium compound.

15. The method according to claim 10, wherein the wet cleaning operation is performed after the applying the reducing agent.

16. A reflective photomask, comprising:
a reflective multilayer stack disposed over a substrate,
wherein the reflective multilayer stack includes a plurality of alternating first layers and second layers;
a capping layer disposed over the reflective multilayer stack; and
a patterned absorber layer disposed over the capping layer,
wherein the reflective photomask has a mean extreme ultraviolet radiation reflectivity of 65.1±1%.

17. The reflective photomask of claim 16, wherein the reflective multilayer stack comprises 40±1 pairs of first and second layers.

18. The reflective photomask of claim 16, further comprising an oxide layer disposed over the patterned absorber layer.

19. The reflective photomask of claim 16, further comprising a black border exposing the substrate surrounding a patterned region of the photomask.

20. The reflective photomask of claim 16, further comprising an intermediate layer disposed between the capping layer and the patterned absorber layer, wherein the intermediate layer is made of a different material than the capping layer and the patterned absorber layer.
